(19) United States
(12) Patent Application Publication
(10) Pub. No.: US 2026/0371674 A1
(43) Pub. Date: Nov. 19, 2026

(54) SEMICONDUCTOR DEVICE INCLUDING MULTIPLE DOPING REGIONS AND METHOD OF MANUFACTURING SAME

(71) Applicant: SAMSUNG ELECTRONICS CO., LTD., Suwon-si (KR)

(72) Inventors: Seunguk HAN, Suwon-si (KR); Jinwoo HAN, Suwon-si (KR); Jeongsu KIM, Suwon-si (KR); Sung-Min PARK, Suwon-si (KR); Bowon YOO, Suwon-si (KR); Sunmi LEE, Suwon-si (KR)

(73) Assignee: SAMSUNG ELECTRONICS CO., LTD., Suwon-si (KR)

(21) Appl. No.: 19/405,745

(22) Filed: Dec. 2, 2025

(30) Foreign Application Priority Data
May 16, 2025 (KR) 10-2025-0063637

(51) Int. Cl. H10D 62/60; H10B 12/00; H10B 80/00; H10D 1/68; H10D 30/01; H10D 80/30; H10W 20/41; H10W 90/00

(52) U.S. Cl. CPC H10D 62/60; H10D 1/714; H10W 20/435; H10B 12/05; H10B 80/00; H10D 30/027; H10D 80/30; H10W 90/792

(57) ABSTRACT

A semiconductor device includes a substrate having a first surface and a second surface opposite to each other, peripheral transistors on the first surface, and a lower insulating layer on the second surface. The substrate includes a first well region and a second well region in the substrate and spaced apart from each other in a horizontal direction parallel to the first and second surfaces, and a lower doping region in the substrate between the first well region and the second well region and adjacent to the second surface. The substrate and the lower doping region include a first dopant having a first conductive type. A concentration of the first dopant in the lower doping region is higher than a concentration of the first dopant in the substrate. The first well region and the second well region have a second conductive type different from the first conductive type.

### CROSS-REFERENCE TO RELATED APPLICATIONS

This U.S. non-provisional patent application claims priority under 35 U.S.C. § 119 of Korean Patent Application No. 10-2025-0063637, filed on May 16, 2025, the entire contents of which are hereby incorporated by reference.

### BACKGROUND

The present disclosure herein relates to a semiconductor device and a method for manufacturing the same, and more particularly, to a semiconductor device including three-dimensionally arranged memory cells and a method for manufacturing the same.

Semiconductor devices capable of storing high-volume data are required for electronic systems that require data storage. Therefore, researches are carried out to develop methods for increasing data storage capacity of semiconductor devices. For example, a semiconductor device including three-dimensionally arranged memory cells instead of two-dimensionally arranged memory cells is proposed as one of methods for increasing the data storage capacity of semiconductor device.

Recently, with an increase in operational speed and reduction in power consumption of electronic devices, semiconductor devices included in such electronic devices are required to have a high operational speed and/or low operational voltage. To satisfy such requirements, more highly integrated semiconductor devices are necessary. However, as semiconductor devices are more highly integrated, electrical characteristics and production yield of the semiconductor devices may deteriorate. Therefore, researches are carried out to improve the electrical characteristics, production yield, and integration density of semiconductor devices.

### SUMMARY

The present disclosure provides a semiconductor device with improved electrical characteristics and a method for manufacturing the same.

The present disclosure also provides a semiconductor device that facilitates high integration and a method for manufacturing the same.

An embodiment of the inventive concept provides a semiconductor device including: a substrate having a first surface and a second surface opposite to each other; peripheral transistors on the first surface of the substrate; and a lower insulating layer on the second surface. The substrate may include a first well region and a second well region that are provided in the substrate and spaced apart from each other in a horizontal direction parallel to the first surface and the second surface of the substrate, and a lower doping region provided in the substrate between the first well region and the second well region and adjacent to the second surface of the substrate. The substrate and the lower doping region may include a first dopant having a first conductive type. A concentration of the first dopant in the lower doping region may be higher than a concentration of the first dopant in the substrate. The first well region and the second well region may have a second conductive type different from the first conductive type.

In an embodiment of the inventive concept, a semiconductor device includes: a cell array structure on a lower substrate; and a peripheral circuit structure on the cell array structure. The peripheral circuit structure may include: a substrate having a first surface and a second surface opposite to each other; peripheral transistors on the first surface of the substrate; and a lower insulating layer between the second surface of the substrate and the cell array structure. The substrate may include a first well region and a second well region that are provided in the substrate and spaced apart from each other in a horizontal direction parallel to the first surface and the second surface of the substrate, and a lower doping region provided in the substrate between the first well region and the second well region and adjacent to the second surface of the substrate. The substrate and the lower doping region may include a first dopant having a first conductive type. A concentration of the first dopant in the lower doping region may be higher than a concentration of the first dopant in the substrate. The first well region and the second well region may have a second conductive type different from the first conductive type.

In an embodiment of the inventive concept, a semiconductor device includes: a substrate having a first surface and a second surface opposite to each other; and peripheral transistors on the first surface of the substrate. The substrate may include: a first well region and a second well region that are provided in the substrate and spaced apart from each other in a horizontal direction parallel to the first surface and the second surface of the substrate; and an upper doping region and a lower doping region that are provided in the substrate between the first well region and the second well region and spaced apart from each other in a vertical direction perpendicular to the first surface and the second surface of the substrate. The substrate, the upper doping region, and the lower doping region may include a first dopant having a first conductive type. A concentration of the first dopant in the lower doping region and a concentration of the first dopant in the upper doping region may be higher than a concentration of the first dopant in the substrate.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a block diagram illustrating a semiconductor device according to some embodiments of the inventive concept;

FIG. 2 is a schematic perspective view illustrating a semiconductor device according to some embodiments of the inventive concept;

FIG. 3 is a schematic perspective view illustrating a cell array structure of a semiconductor device according to some embodiments of the inventive concept;

FIG. 4 is a plan view of a semiconductor device according to some embodiments of the inventive concept;

FIG. 5 is a cross-sectional view taken along line A-A′ of FIG. 4;

FIG. 6 is an enlarged view of a portion of the peripheral circuit structure of FIG. 5;

FIG. 7 is a graph showing a doping profile of the first portion of FIG. 6;

FIG. 8, which is a diagram illustrating a semiconductor device according to some embodiments of the inventive concept, is an enlarged view of a portion of the peripheral structure of FIG. 5;

FIGS. 9, 11, 13, 15, 17, 19, and 21 are plan views illustrating a method for manufacturing a semiconductor device according to some embodiments of the inventive concept;

FIGS. 10, 12, 14, 16, 18, 20, and 22 are cross-sectional views taken along line A-A′ of FIGS. 9, 11, 13, 15, 17, 19, and 21, respectively;

FIGS. 23, 25, and 27 are cross-sectional views illustrating a method for manufacturing a semiconductor device according to some embodiments of the inventive concept;

FIGS. 24, 26, and 28 are enlarged views of portions of FIGS. 23, 25, and 27, respectively;

FIG. 29 is a cross-sectional view of a semiconductor device, taken along line A-A′ of FIG. 4, according to some embodiments of the inventive concept;

FIGS. 30, 32, and 34 are cross-sectional views illustrating a method for manufacturing a semiconductor device according to some embodiments of the inventive concept; and

FIGS. 31, 33, and 35 are enlarged views of portions of FIGS. 30, 32, and 34, respectively.

### DETAILED DESCRIPTION

Hereinafter, embodiments of the inventive concept will be described in detail with reference to the accompanying drawings.

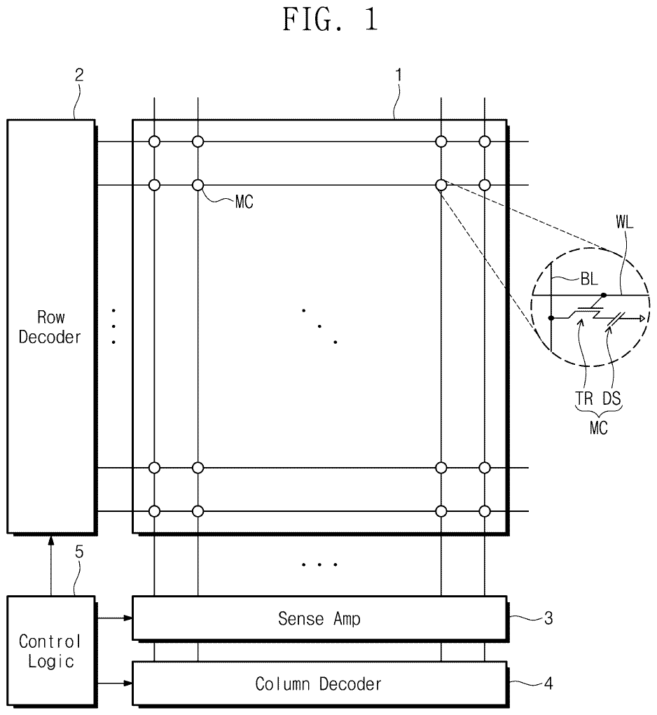

FIG. 1 is a block diagram illustrating a semiconductor device according to some embodiments of the inventive concept.

Referring to FIG. 1, the semiconductor device may include a memory cell array 1, a row decoder 2, a sense amplifier 3, a column decoder 4, and a control logic 5.

The memory cell array 1 may include a plurality of memory cells MC two-dimensionally or three-dimensionally arranged. Each of the memory cells MC may be connected between a word line WL and a bit line BL intersecting each other. The memory cells MC may each include a selection element TR and a data storage element DS. The selection element TR and the data storage element DS may be electrically connected to each other. The selection element TR may be connected to the word line WL and the bit line BL and provided at an intersection of the word line WL and the bit line BL.

The selection element TR may include a field effect transistor. The data storage element DS may include a capacitor, a magnetic tunnel junction pattern, or a variable resistor. When the selection element TR includes a field effect transistor, a gate terminal of the transistor may be connected to the word line WL, and source/drain terminals of the transistor may be respectively connected to the bit line BL and the data storage element DE.

The row decoder 2 may decode an externally input address and select any one of the word lines WL of the memory cell array 1. The address decoded in the row decoder 2 may be provided to a row driver (not shown), and the row driver may provide predetermined voltages to a selected word line WL and non-selected word lines WL respectively in response to control by control circuits.

The sense amplifier 3 may sense and amplify a voltage difference between a reference bit line and the bit line BL selected according to an address decoded by the column decoder 4 and output the amplified voltage difference.

The column decoder 4 may provide a data transfer path between the sense amplifier 3 and an external device (e.g., memory controller). The column decoder 4 may decode an externally input address and select any one of the bit lines BL of the memory cell array 1. The control logic 5 may generate a control signal for controlling an operation of writing or reading data to or from the memory cell array 1.

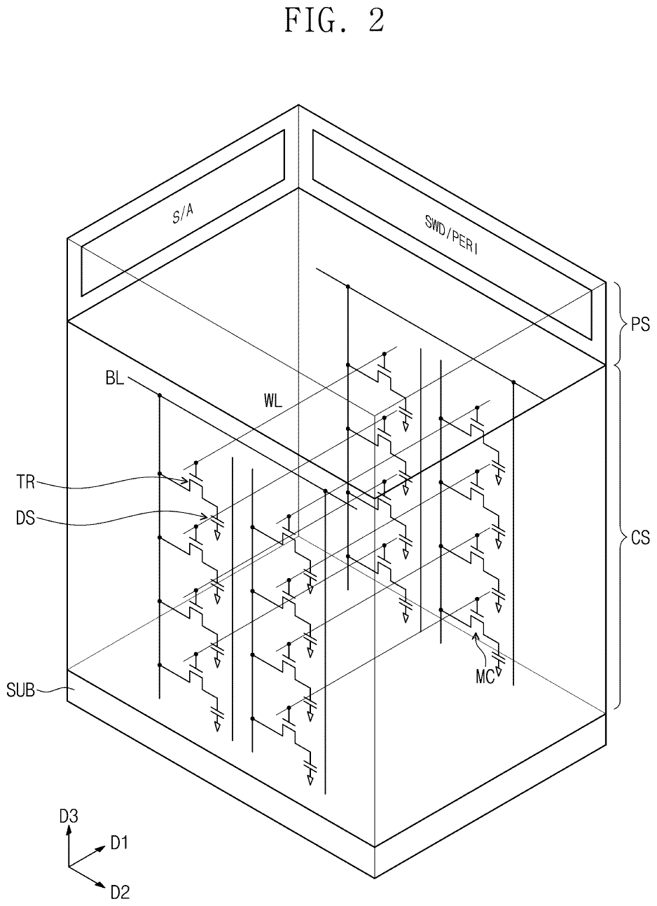

FIG. 2 is a schematic perspective view illustrating a semiconductor device according to some embodiments of the inventive concept.

Referring to FIG. 2, the semiconductor memory device may include a cell array structure CS on a lower substrate SUB and a peripheral circuit structure PS on the cell array structure CS. The cell array structure CS may be disposed between the lower substrate SUB and the peripheral circuit structure PS. In the present disclosure, a first direction D1 and a second direction D2 may be directions parallel to an upper surface of the lower substrate SUB and intersecting each other, and a third direction D3 may be a direction perpendicular to the upper surface of the lower substrate SUB. The first direction D1 and the second direction D2 may be referred to as horizontal directions, and the third direction D3 may be referred to as a vertical direction. The peripheral circuit structure PS and the cell array structure CS may be stacked on the lower substrate SUB in the third direction D3.

The peripheral circuit structure PS may include a core and peripheral circuits. The core and peripheral circuits may include the row and column decoders 2 and 4, the sense amplifier 3, and the control logic 5 described above with reference to FIG. 1.

The cell array structure CS may include the bit lines BL, the word lines WL, and the memory cells MC therebetween. Each of the memory cells MC may be connected to one word line WL and one bit line BL. The memory cells MC may be three-dimensionally arranged on the lower substrate SUB in the first direction D1, the second direction D2, and the third direction D3. The memory cells MC may each include a selection element TR and a data storage element DS. According to some embodiments, the selection element TR may include a field effect transistor, and the data storage element DS may include a capacitor. The bit lines BL, the word lines WL, and the memory cells MC are substantially the same as the bit lines BL, the word lines WL, and the memory cells MC described above with reference to FIG. 1.

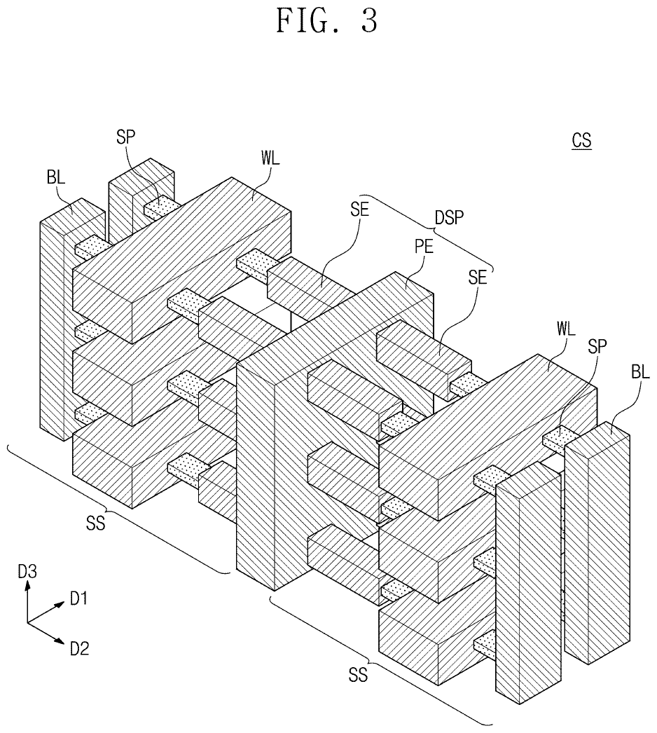

FIG. 3 is a schematic perspective view illustrating a cell array structure of a semiconductor device according to some embodiments of the inventive concept.

Referring to FIG. 3, the cell array structure CS of the semiconductor device may include stack structures SS neighboring each other and a plate electrode PE between the stack structures SS. The plate electrode PE may extend in the first direction D1, and the stack structures SS may be spaced apart from each other in the second direction D2 with the plate electrode PE therebetween. The plate electrode PE may extend in the third direction D3 perpendicular to both of the first direction D1 and the second direction D2.

The stack structures SS may each include a plurality of word lines WL extending in the first direction D1 and spaced apart from each other in the third direction D3, a plurality of semiconductor patterns SP extending in the second direction D2 and spaced apart from each other in the first direction D1 and the third direction D3, a plurality of bit lines BL extending in the third direction D3 and spaced apart from each other in the first direction D1, and a plurality of storage electrodes SE respectively connected to the plurality of semiconductor patterns SP.

The semiconductor patterns SP spaced apart from each other in the first direction D1 among the plurality of semiconductor patterns SP may extend in the second direction D2 and penetrate a corresponding word line WL among the plurality of word lines WL. The semiconductor patterns SP spaced apart from each other in the third direction D3 among the plurality of semiconductor patterns SP may extend in the second direction D2 and respectively penetrate the plurality of word lines WL. The plurality of bit lines BL may each extend in the third direction D3 and be connected in common to the semiconductor patterns SP spaced apart from each other in the third direction D3. The plurality of storage electrodes SE may be connected in common to the plate electrode PE. The stack structures SS may be arranged so as to be mirror symmetric with the plate electrode PE therebetween. The plurality of storage electrodes SE and the plate electrode PE may constitute a data storage pattern DSP.

The stack structures SS and the plate electrode PE may constitute the memory cell array 1 of FIG. 1 and the cell array structure CS of FIG. 2. Each semiconductor pattern SP and the corresponding word line WL connected thereto may correspond to the selection element TR and the word line WL described above with reference to FIGS. 1 and 2. The corresponding bit line BL connected to each semiconductor pattern SP may correspond to the bit line BL described above with reference to FIGS. 1 and 2. The corresponding storage electrode SE connected to each semiconductor pattern SP and the plate electrode PE may constitute the data storage device DS described above with reference to FIGS. 1 and 2.

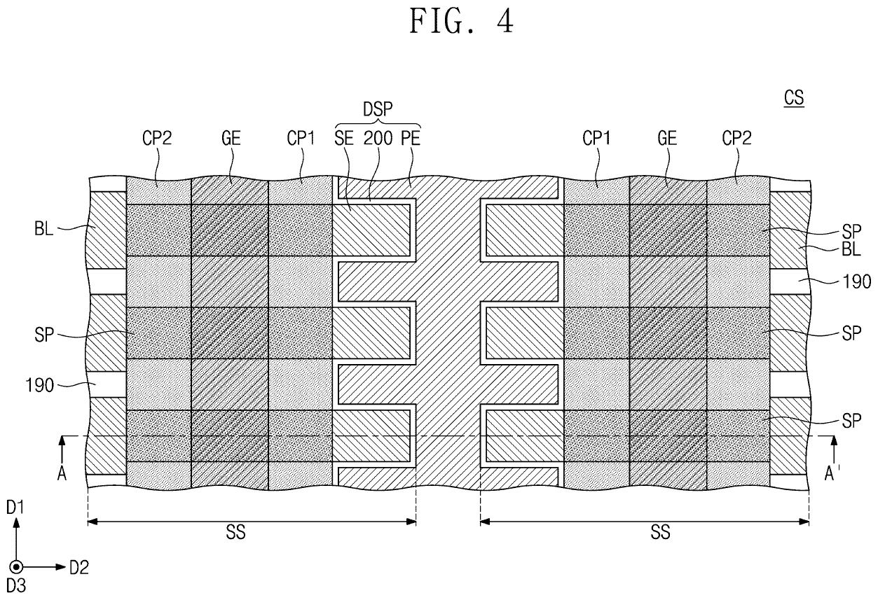

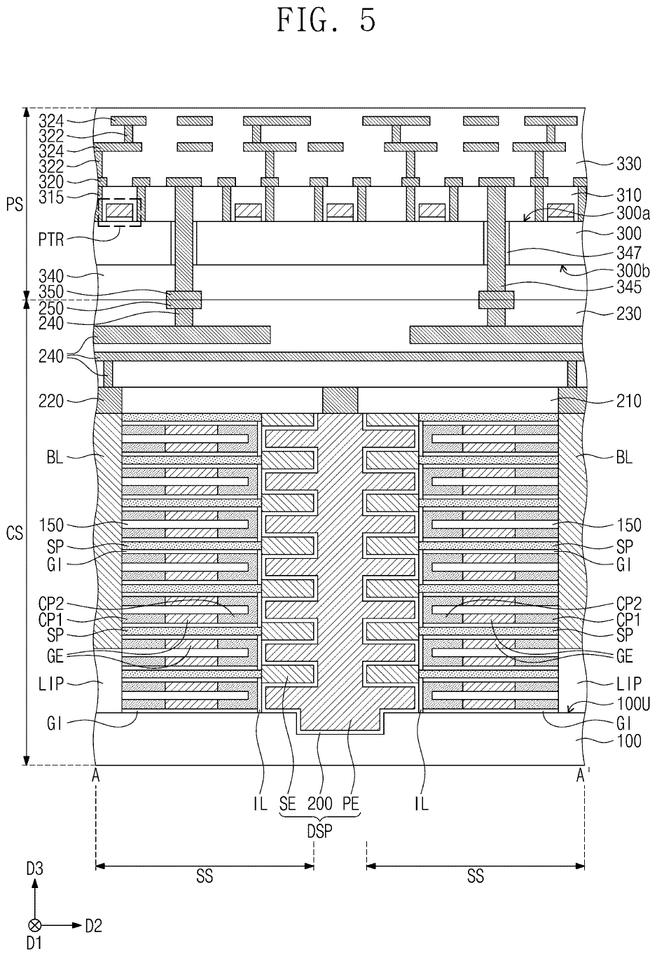

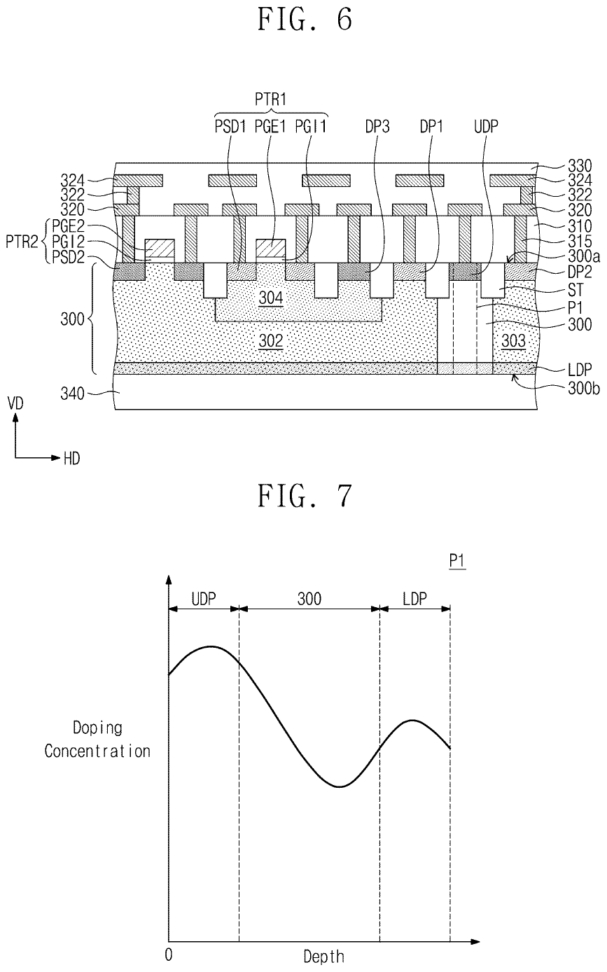

FIG. 4 is a plan view of a semiconductor device according to some embodiments of the inventive concept. FIG. 5 is a cross-sectional view taken along line A-A′ of FIG. 4. FIG. 6 is an enlarged view of a portion of the peripheral circuit structure of FIG. 5. FIG. 7 is a graph showing a doping profile of the first portion of FIG. 6. For simple illustration, the peripheral circuit structure of FIG. 5 is omitted in FIG. 4.

Referring to FIGS. 4 and 5, the semiconductor device may include the cell array structure CS on a lower substrate 100 and the peripheral circuit structure PS on the cell array structure CS. The cell array structure CS and the peripheral circuit structure PS may be sequentially stacked in the third direction D3 perpendicular to an upper surface 100U of the lower substrate 100. The cell array structure CS may be disposed between the lower substrate 100 and the peripheral circuit structure PS. The lower substrate 100 may be a semiconductor substrate, an insulator substrate, a silicon-on-insulator (SOI) substrate, or a germanium-on-insulator (GOI) substrate. The semiconductor substrate may be a silicon substrate, a germanium substrate, or a silicon-germanium substrate, for example.

The cell array structure CS may include the stack structures SS and the plate electrode PE between the stack structures SS. The plate electrode PE may extend in the first direction D1, and the stack structures SS may be spaced apart from each other in the second direction D2 with the plate electrode PE therebetween. The first direction D1 and the second direction D2 may be parallel with the upper surface 100U of the lower substrate 100 and may intersect each other. The plate electrode PE may extend in the third direction D3 between the stack structures SS.

The stack structures SS may each include the plurality of semiconductor patterns SP extending in the second direction D2. The plurality of semiconductor patterns SP may be spaced apart from the upper surface 100U of the substrate 100 in the third direction D3 and spaced apart from each other in the first direction D1 and the third direction D3. The plurality of semiconductor patterns SP may include at least one of a semiconductor material, an oxide semiconductor, or a two-dimensional semiconductor material. The plurality of semiconductor patterns SP may include at least one of silicon (e.g., single-crystal silicon), germanium, or silicon-germanium, for example. The plurality of semiconductor patterns SP may include, for example, InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, InₓGa_{y}O, or a combination thereof. The plurality of semiconductor patterns SP may include indium gallium zinc oxide (IGZO). The plurality of semiconductor patterns SP may include, for example, graphene, carbon nanotube, or combination thereof.

The stack structures SS may each include a plurality of gate electrodes GE extending in the first direction D1 and spaced apart from each other in the third direction D3. The plurality of gate electrodes GE may function as the word lines WL of FIGS. 1 to 3. The plurality of gate electrodes GE may be spaced apart from the upper surface 100U of the lower substrate 100 in the third direction D3. According to some embodiments, a lowermost gate electrode GE and an uppermost gate electrode GE among the plurality of gate electrodes GE may be a dummy gate electrode.

The semiconductor patterns SP spaced apart from each other in the first direction D1 among the plurality of semiconductor patterns SP may extend in the second direction D2 and penetrate the corresponding gate electrode GE among the plurality of gate electrodes GE. The semiconductor patterns SP spaced apart from each other in the third direction D3 among the plurality of semiconductor patterns SP may extend in the second direction D2 and respectively penetrate the plurality of gate electrodes GE.

The plurality of gate electrodes GE may include at least one of metal (e.g., Ti, Mo, W, Cu, Al, Ta, Ru, Ir, Co, etc.), metal silicide (e.g., silicide of Ti, Mo, W, Cu, Al, Ta, Ru, Ir, Co, etc.), or conductive metal nitride (e.g., nitride of Ti, Mo, W, Cu, Al, Ta, Ru, Ir, Co, etc.).

The stack structures SS may each include a plurality of mold patterns 150 interposed between the plurality of gate electrodes GE and spaced apart from each other in the third direction D3. The plurality of mold patterns 150 may extend between the plurality of gate electrodes GE in the first direction D1. The plurality of gate electrodes GE and the plurality of mold patterns 150 may be alternately arranged in the third direction D3. The plurality of mold patterns 150 may extend between the plurality of semiconductor patterns SP in the second direction D2. The plurality of mold patterns 150 may include an insulating material such as silicon oxide, silicon nitride, and/or silicon oxynitride.

The stack structures SS may each further include a first capping pattern CP1 and a second capping pattern CP2 arranged on both sides of each of the plurality of gate electrodes GE. The first capping pattern CP1 and the second capping pattern CP2 may extending in the first direction D1. The plurality of semiconductor patterns SP may each extend in the second direction D2 and penetrate the first capping pattern CP1 and the second capping pattern CP2. Each of the plurality of gate electrodes GE, the first capping pattern CP1, and the second capping pattern CP2 may be interposed between a pair of mold patterns 150 neighboring each other in the third direction D3 among the plurality of mold patterns 150. The first and second capping patterns CP1 and CP2 may include an insulating material such as silicon oxide, silicon nitride, and/or silicon oxynitride.

The stack structures SS may each further include a gate insulating layer GI interposed between each of the plurality of semiconductor patterns SP and each of the plurality of gate electrodes GE. The plurality of semiconductor patterns SP may each be spaced apart from each of the plurality of gate electrodes GE with the gate insulating layer GI therebetween. The gate insulating layer GI may extend in the second direction D2 and be interposed between each of the plurality of semiconductor patterns SP and the first capping pattern CP1 and between each of the plurality of semiconductor patterns SP and the second capping pattern CP2. The plurality of semiconductor patterns SP may each be spaced apart from the first capping pattern CP1 and the second capping pattern CP2.with the gate insulating layer GI therebetween. The gate insulating layer GI may be interposed between the lower substrate 100 and the lowermost gate electrode GE. The lowermost first capping pattern CP1 and the lowermost second capping pattern CP2 may be arranged on both sides of the lowermost gate electrode GE, and the gate insulating layer GI may extend between the lower substrate 100 and the lowermost first capping pattern CP1 and between the lower substrate 100 and the lowermost second capping pattern CP2. The gate insulating layer GI may include, for example, at least one of silicon oxide or a high-k material. The high-k material may be a material having a higher dielectric constant than a dielectric constant of silicon oxide, and may include metal oxide or metal oxynitride, for example. The high-k material may include, for example, at least one of HfO₂, HfSiO, HfSiON, HfTaO, HfTiO, HfZrO, ZrO₂, or Al₂O₃.

The stack structures SS may each include a plurality of bit lines BL spaced apart from each other in the first direction D1 and extending in the third direction D3. The plurality of bit lines BL may each extend in the third direction D3 and be electrically connected to the semiconductor patterns SP spaced apart from each other in the third direction D3. The plurality of bit lines BL may include at least one of a doped semiconductor material (e.g., doped silicon, doped germanium, etc.), metal (e.g., Ti, Mo, W, Cu, Al, Ta, Ru, Ir, Co, etc.), metal silicide (e.g., silicide of Ti, Mo, W, Cu, Al, Ta, Ru, Ir, Co, etc.), or conductive metal nitride (e.g., nitride of Ti, Mo, W, Cu, Al, Ta, Ru, Ir, Co, etc.). According to some embodiments, the plurality of bit lines BL may include a carbon-based two-dimensional material (e.g., graphene), a carbon-based three-dimensional material (e.g., carbon nanotube), or a combination thereof.

The stack structures SS may each further include lower insulating patterns LIP interposed between the plurality of bit lines BL and the lower substrate 100. The lower insulating patterns LIP may be arranged under the plurality of bit lines BL, respectively and spaced apart from each other in the first direction D1. The lower insulating patterns LIP may each extend in the third direction D3 and cover a side surface of at least one semiconductor pattern SP among the plurality of semiconductor patterns SP. The lower insulating patterns LIP may include an insulating material such as silicon oxide, silicon nitride, and/or silicon oxynitride.

The stack structures SS may each further include a buried insulating layer 190 extending in the third direction D3 between the plurality of bit lines BL and between the lower insulating patterns LIP. The plurality of bit lines BL may each penetrate an upper portion of the buried insulating layer 190 in the third direction D3, and the lower insulating patterns LIP may each penetrate a lower portion of the buried insulating layer 190 in the third direction D3. The buried insulating layer 190 may include an insulating material such as silicon oxide, silicon nitride, and/or silicon oxynitride.

The stack structures SS may each further include a plurality of storage electrodes SE respectively connected to the plurality of semiconductor patterns SP. The plurality of storage electrodes SE may be spaced apart from each other in the first direction D1 and the third direction D3. The plurality of storage electrodes SE may be spaced apart from the plurality of bit lines BL in the second direction D2, and the plurality of semiconductor patterns SP, the plurality of gate electrodes GE, the first and second capping patterns CP1 and CP2, the plurality of mold patterns 150, and the gate insulating layer GI may be arranged between the plurality of storage electrodes SE and the plurality of bit lines BL. The plurality of storage electrodes SE may be electrically connected to the plate electrode PE.

The plurality of storage electrodes SE and the plate electrode PE may include at least one of impurity-doped silicon (Si), impurity-doped silicon germanium (SiGe), metal (e.g., Ti, Mo, W, Cu, Al, Ta, Ru, Ir, Co, Pt, Au, Ag, etc.), metal nitride (e.g., nitride of Ti, Mo, W, Cu, Al, Ta, Ru, Ir, Co, Pt, Au, Ag, etc., titanium silicon nitride (e.g., TiSiN), titanium aluminum nitride (e.g., TiAlN), and tantalum aluminum nitride (e.g., TaAlN), etc.), conductive oxide (e.g., PtO, RuO₂, IrO₂, SRO(SrRuO₃), BSRO((Ba, Sr)RuO₃), CRO(CaRuO₃), LSCo), or metal silicide.

The stack structures SS may each further include a dielectric layer 200 interposed between the plurality of storage electrodes SE and the plate electrode PE. The dielectric layer 200 may conformally cover each of the plurality of storage electrodes SE and extend between the plurality of storage electrodes SE in the first direction D1 and the third direction D3. The dielectric layer 200 may extend between the lower substrate 100 and the plate electrode PE in the second direction D2. According to some embodiments, a lower portion of the plate electrode PE may extend into the lower substrate 100 in the third direction D3, and the dielectric layer 200 may extend between the lower portion of the plate electrode PE and an inner surface of the lower substrate 100. The plate electrode PE may be spaced apart from the lower substrate 100 with the dielectric layer 200 therebetween. The stack structures SS may each further include an insulating layer IL interposed between the fist capping pattern CP1 and the dielectric layer 200 between the plurality of storage electrodes SE.

The plurality of storage electrodes SE may each be spaced apart from the plate electrode PE with the dielectric layer 200 therebetween. The plurality of storage electrodes SE, the plate electrode PE, and the dielectric layer 200 may constitute a data storage pattern DSP, and the data storage pattern DSP may be a capacitor, for example. The dielectric layer 200 may include at least one of metal oxide such as HfO₂, ZrO₂, Al₂O₃, La₂O₃, Ta₂O₃, and TiO₂ or perovskite-structure dielectric material such as SrTiO₃(STO), (Ba, Sr)TiO₃(BST), BaTiO₃, PZT, and PLZT. The insulating layer IL may include an insulating material such as silicon oxide, silicon nitride, and/or silicon oxynitride. The stack structures SS may be arranged so as to be mirror symmetric with the plate electrode PE therebetween.

The plurality of gate electrodes GE may each surround a channel region of the corresponding semiconductor pattern SP among the plurality of semiconductor patterns SP. The plurality of gate electrodes GE may each have a gate-all-around structure surrounding the channel region of the corresponding semiconductor pattern SP. The first capping pattern CP1 may surround a first contact region of the corresponding semiconductor pattern SP, and the second capping pattern CP2 may surround a second contact region of the corresponding semiconductor pattern SP. The first contact region and the second contact region of the corresponding semiconductor pattern SP may have an N-type or P-type conductivity, and may be regions in which N-type or P-type dopant is injected. The first contact region and the second contact region of the corresponding semiconductor pattern SP may have the same conductive type. The first contact region and the second contact region of the corresponding semiconductor pattern SP may also be referred to as a first source/drain region and a second source/drain region, respectively. The channel region of the corresponding semiconductor pattern SP may be an intrinsic semiconductor region. The first contract region of the corresponding semiconductor pattern SP may be connected to the corresponding storage electrode SE among the plurality of storage electrodes SE, and the second contact region of the corresponding semiconductor pattern SP may be connected to the corresponding bit line BL among the plurality of bit lines BL.

The cell array structure CS may further include a first cell insulating layer 210 and first cell conductive patterns 220 arranged on the stack structures SS and the plate electrode PE. The first cell conductive patterns 220 may be connected to the bit lines BL and the plate electrode PE. The bit lines BL may each be connected to the corresponding first cell conductive pattern 220 among the first cell conductive patterns 220, and the plate electrode PE may be connected to the corresponding first cell conductive pattern 220 among the first cell conductive patterns 220. The first cell insulating layer 210 may cover the first cell conductive patterns 220.

The cell array structure CS may further include a second cell insulating layer 230, second cell conductive patterns 240, and cell bonding pads 250 arranged on the first cell insulating layer 210. The second cell conductive patterns 240 may be arranged between the first cell conductive patterns 220 and the cell bonding pads 250 and may electrically connect the first cell conductive patterns 220 and the cell bonding pads 250. The second cell insulating layer 230 may cover the second cell conductive patterns 240 and the cell bonding pads 250 and expose upper surfaces of the cell bonding pads 250.

The first cell insulating layer 210 and the second cell insulating layer 230 may include an insulating material such as silicon oxide, silicon nitride, and/or silicon oxynitride. The first cell conductive patterns 220, the second cell conductive patterns 240, and the cell bonding pads 250 may include a conductive material such as metal.

Referring to FIGS. 5 and 6, the peripheral circuit structure PS may include a substrate 300 having a first surface 300a and a second surface 300b opposite to each other, peripheral transistors PTR on the first surface 300a of the substrate, and a lower insulating layer 340 on the second surface 300b of the substrate 300. The first surface 300a and the second surface 300b of the substrate 300 may be opposite to each other in the third direction D3. The third direction D3 may be referred to as a vertical direction VD perpendicular to the first surface 300a and the second surface 300b of the substrate 300. The substrate 300 may be a semiconductor substrate (e.g., silicon substrate, germanium substrate, or silicon-germanium substrate), an insulator substrate, a silicon-on-insulator (SOI) substrate, or a germanium-on-insulator (GOI) substrate.

The substrate 300 may include a first well region 302 and a second well region 303 provided in the substrate 300 and spaced apart from each other in a horizontal direction HD parallel to the first surface 300a and the second surface 300b of the substrate 300. The first well region 302 and the second well region 303 may extend from the first surface 300a of the substrate 300 toward the second surface 300b of the substrate 300, and a lower portion of the first well region 302 and a lower portion of the second well region 303 may be adjacent to the second surface 300b of the substrate 300. A portion of the substrate 300 may be interposed between the first well region 302 and the second well region 303. The substrate 300 may have a first conductive type, and the first well region 302 and the second well region 303 may have a second conductive type different from the first conductive type. For example, the first conductive type may be a P type, and the second conductive type may be an N type. For another example, the first conductive type may be an N type, and the second conductive type may be a P type. In some embodiments, the first well region 302 and the second well region 303 may have a second dopant.

The substrate 300 may further include an upper doping region UDP and a lower doping region LDP provided in the substrate 300 between the first well region 302 and the second well region 303 and spaced apart from each other in the vertical direction VD. The upper doping region UDP may be adjacent to the first surface 300a of the substrate 300, and the lower doping region LDP may be adjacent to the second surface 300b of the substrate 300. A portion of the substrate 300 may be interposed between the upper doping region UDP and the lower doping region LDP. At least a portion of the lower doping region LDP may be interposed between the first well region 302 and the second well region 303.

According to some embodiments, the lower doping region LDP may extend into the first well region 302 and the second well region 303 in the horizontal direction HD. Accordingly, a portion of the lower doping region LDP may overlap the portion of the first well region 302, and another portion of the lower doping region LDP may overlap the portion of the second well region 303. Still another portion of the lower doping region LDP may be interposed between the first well region 302 and the second well region 303.

FIG. 7 is a graph showing a concentration change of dopant in the vertical direction VD from the first surface 300a to the second surface 300b. Referring to FIGS. 6 and 7, the substrate 300, the upper doping region UDP, and the lower doping region LDP may include a first dopant having the first conductive type. The upper doping region UDP and the lower doping region LDP may have the same conductive type (e.g., the first conductive type) as the substrate 300. For example, the first conductive type may be a P type, and the first dopant may be boron (B). The upper doping region UDP may include a portion with a higher concentration of the first dopant than the substrate 300. The lower doping region LDP may include a portion with a higher concentration of the first dopant than the substrate 300. A first maximum value of the concentration of the first dopant in the upper doping region UDP may be higher than the concentration of the first dopant in the substrate 300. A second maximum value of the concentration of the first dopant in the lower doping region LDP may be higher than a minimum value of the concentration of the first dopant in the substrate 300. The first maximum value of the concentration of the first dopant in the upper doping region UDP may be greater than the second maximum value of the concentration of the first dopant in the lower doping region LDP. The concentration of the first dopant in the substrate 300 may include a section in which the concentration of the first dopant in the substrate 300 increases after decreasing in the vertical direction VD. For example, between the first well region 302 and the second well region 303, the concentration of the first dopant may decrease in a direction from a region adjacent to the first surface 300a (i.e., the upper doping region UDP) of the substrate 300 to the inside of the substrate 300 and may increase in a direction to a region adjacent to the second surface 300b (e.g., the lower oping region LDP) of the substrate 300. Between the first well region 302 and the second well region 303, the concentration of the first dopant may be maximum at the region adjacent to the first surface 300a (i.e., the upper doping region UDP) of the substrate 300.

Referring back to FIGS. 5 and 6, the substrate 300 may further include a first doping region DP1 adjacent to the first surface 300a of the substrate 300 and disposed in the first well region 302 and a second doping region DP2 adjacent to the first surface 300a of the substrate 300 and disposed in the second well region 303. The first doping region DP1 may have the same conductive type (e.g., the second conductive type) as the first well region 302, and the second doping region DP2 may have the same conductive type (e.g., the second conductive type) as the second well region 303. The first well region 302, the first doping region DP1, the second well region 303, and the second doping region DP2 may include a second dopant having the second conductive type. For example, the second conductive type may be an N type, and the second dopant may be phosphorus (P). A concentration of the second dopant in the first doping region DP1 may be higher than a concentration of the second dopant in the first well region 302. A concentration of the second dopant in the second doping region DP2 may be higher than a concentration of the second dopant in the second well region 303. The upper doping region UDP may be disposed between the first doping region DP1 and the second doping region DP2.

The substrate 300 may further include a third well region 304 adjacent to the first surface 300a of the substrate 300 and disposed in the first well region 302 and a third doping region DP3 adjacent to the first surface 300a of the substrate 300 and disposed in the third well region 304. The third well region 304 and the third doping region DP3 may be spaced apart from the first doping region DP1 in the horizontal direction HD. The third well region 304 and the third doping region DP3 may have the same conductive type (e.g., the first conductive type) as the substrate 300. The third well region 304 and the third doping region DP3 may include the first dopant having the first conductive type. A concentration of the first dopant in the third doping region DP3 may be higher than a concentration of the first dopant in the third well region 304.

The peripheral transistors PTR may include a first peripheral transistor PTR1 disposed on the third well region 304 and a second peripheral transistor PTR2 disposed on the first well region 302. The first peripheral transistor PTR1 may be spaced apart from the third doping region DP3 in the horizontal direction HD. The first peripheral transistor PTR1 may include a first peripheral gate electrode PGE1 on the third well region 304, a first peripheral gate insulating pattern PGI1 between the third well region 304 and the first peripheral gate electrode PGE1, and first peripheral source/drain regions PSD1 arranged on both sides of the first peripheral gate electrode PGE1 and in the third well region 304. The first peripheral gate electrode PGE1 may include a conductive material (e.g., doped semiconductor material, metal, etc.), and the first peripheral gate insulating pattern PGI1 may include, for example, at least one of silicon oxide or a high-k material. The high-k material may be a material having a higher dielectric constant than a dielectric constant of silicon oxide, and may include metal oxide or metal oxynitride, for example. The high-k material may include, for example, at least one of HfO₂, HfSiO, HfSiON, HfTaO, HfTiO, HfZrO, ZrO₂, or Al₂O₃. The first peripheral source/drain regions PSD1 may have a conductive type different from the third well region 304 and have the second conductive type, for example.

The second peripheral transistor PTR2 may be spaced apart from the first peripheral transistor PTR1, the third well region 304, the third doping region DP3, and the first doping region DP1 in the horizontal direction HD. The second peripheral transistor PTR2 may include a second peripheral gate electrode PGE2 on the first well region 302, a second peripheral gate insulating pattern PGI2 between the first well region 302 and the second peripheral gate electrode PGE2, and second peripheral source/drain regions PSD2 arranged on both sides of the second peripheral gate electrode PGE2 and in the first well region 302. The second peripheral gate electrode PGE2 may include a conductive material (e.g., doped semiconductor material, metal, etc.), and the second peripheral gate insulating pattern PGI2 may include, for example, at least one of silicon oxide or a high-k material. The second peripheral source/drain regions PSD2 may have a conductive type different from the first well region 302 and have the first conductive type, for example.

The peripheral circuit structure PS may further include device isolation patterns ST arranged in the substrate 300 so as to be adjacent to the first surface 300a of the substrate 300. The device isolation patterns ST may be interposed between the upper doping region UDP and the first doping region DP1 and between the upper doping region UDP and the second doping region DP2, and may extend between the first well region 302 and the substrate 300 and between the second well region 303 and the substrate 300. The device isolation patterns ST may be interposed between the first doping region DP1 and the third doping region DP3 and may extend between the first well region 302 and the third well region 304. The device isolation patterns ST may be arranged between the first peripheral transistor PTR1 and the third doping region DP3 and may extend into the third well region 304. The device isolation patterns ST may be arranged between the first peripheral transistor PTR1 and the second peripheral transistor PTR2 and may extend between the first well region 302 and the third well region 304. The device isolation patterns ST may include an insulating material such as silicon oxide, silicon nitride, and/or silicon oxynitride.

The peripheral circuit structure PS may further include a first upper insulating layer 310 disposed on the first surface 300a of the substrate 300 and covering the peripheral transistors PTR, peripheral conductive contacts 315 arranged in the first upper insulating layer 310, peripheral wiring patterns 320, 322, and 324 on the first upper insulating layer 310, and a second upper insulating layer 330 disposed on the first upper insulating layer 310 and covering the peripheral wiring patterns 320, 322, and 324. The peripheral conductive contacts 315 may penetrate the first upper insulating layer 310 in the vertical direction VD and may be respectively connected to the upper doping region UDP, the first to third doping regions DP1 to DP3, the first peripheral source/drain regions PSD1, and the second peripheral source/drain regions PSD2. The peripheral wiring patterns 320, 322, and 324 may include first wiring lines 320 arranged on the first upper insulating layer 310 and respectively connected to the peripheral conductive contacts 315, second wiring lines 324 spaced apart from the first wiring lines 320 in the vertical direction VD, and wiring contacts 322 arranged between the first wiring lines 320 and the second wiring lines 324. The wiring contacts 322 may electrically connect the first wiring lines 320 and the second wiring lines 324. The peripheral conductive contacts 315 and the peripheral wiring patterns 320, 322, and 324 may include a conductive material (e.g., metal). The first upper insulating layer 310 and the second upper insulating layer 330 may include an insulating material such as silicon oxide, silicon nitride, and/or silicon oxynitride.

The peripheral circuit structure PS may further include a vertical conductive pattern 345 penetrating the substrate 300, the lower insulating layer 340, and the first upper insulating layer 310 in the vertical direction VD (e.g., the third direction D3) and a side insulating pattern 347 between the substrate 300 and the vertical conductive pattern 345. The vertical conductive pattern 345 may be connected to the corresponding peripheral wiring pattern 320 among the peripheral wiring patterns 320, 322, and 324. For example, the vertical conductive pattern 345 may be connected to the corresponding first wiring line 320 among the first wiring lines 320. The vertical conductive pattern 345 may be electrically isolated by the side insulating pattern 347 from the substrate 300. The vertical conductive pattern 345 may include a conductive material (e.g., metal). The side insulating pattern 347 may include an insulating material such as silicon oxide, silicon nitride, and/or silicon oxynitride.

According to some embodiments, the peripheral circuit structure PS may further include peripheral bonding pads 350 arranged in the lower insulating layer 340. The lower insulating layer 340 may expose lower surfaces of the peripheral bonding pads 350. The vertical conductive pattern 345 may extend in the vertical direction VD (e.g., the third direction D3) and be respectively connected to the peripheral bonding pads 350. The vertical conductive pattern 345 may electrically connect each of the peripheral bonding pads 350 and the corresponding first wiring line 320. The lower insulating layer 340 may include an insulating material such as silicon oxide, silicon nitride, and/or silicon oxynitride. The peripheral bonding pads 350 may include a conductive material (e.g., metal).

According to some embodiments, the cell bonding pads 250 of the cell array structure CS may be respectively connected to the peripheral bonding pads 350 of the peripheral circuit structure PS. The cell bonding pads 250 of the cell array structure CS may be in contact with the peripheral bonding pads 350 of the peripheral circuit structure PS, respectively, and the second cell insulating layer 230 of the cell array structure CS may be in contact with the lower insulating layer 340 of the peripheral circuit structure PS. That is, the cell array structure CS and the peripheral circuit structure PS may be coupled using a hybrid bonding method and may be electrically connected to each other through the cell bonding pads 250 and the peripheral bonding pads 350.

During a manufacturing process for forming the peripheral circuit structure PS, a grinding process may be performed on the second surface 300b of the substrate 300, and the lower insulating layer 340 may be formed on the second surface 300b of the substrate 300 after the grinding process. In this case, a charge layer (e.g., positive charge) may be formed on an interface between the second surface 300b of the substrate 300 and the lower insulating layer 340, and thus carrier charge (e.g., negative charge) may be induced in the substrate 300 between the first well region 302 and the second well region 303. As a result, electrical isolation between the first well region 302 and the second well region 303 may be difficult.

According to the inventive concept, the lower doping region LDP may be formed in the substrate 300 between the first well region 302 and the second well region 303 and may be adjacent to the second surface 300b of the substrate 300. The lower doping region LDP may have the same conductive type (e.g., the first conductive type) as the substrate 300, and the concentration of the first dopant in the lower doping region LDP may be higher than the concentration of the first dopant in the substrate 300. Therefore, even if a charge layer (e.g., positive charge) is formed on an interface between the second surface 300b of the substrate 300 and the lower insulating layer 340, carrier charge (e.g., negative charge) may be suppressed from being induced in the substrate 300 between the first well region 302 and the second well region 303, and, as a result, electrical isolation between the first well region 302 and the second well region 303 may be improved. Therefore, electrical characteristics of a semiconductor device including the peripheral circuit structure PS may be improved.

In addition, the peripheral circuit structure PS may be stacked on the cell array structure CS in the third direction D3 (i.e., the vertical direction VD), and the lower insulating layer 340 of the peripheral circuit structure PS is in contact with the second cell insulating layer 230 of the cell array structure CS, and thus the cell array structure CS and the peripheral circuit structure PS may be easily bonded. Therefore, a semiconductor device including the cell array structure CS and the peripheral circuit structure PS may be highly integrated with ease.

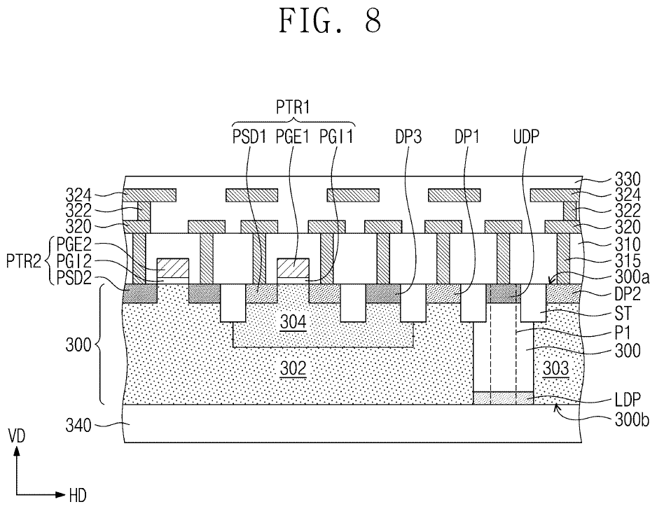

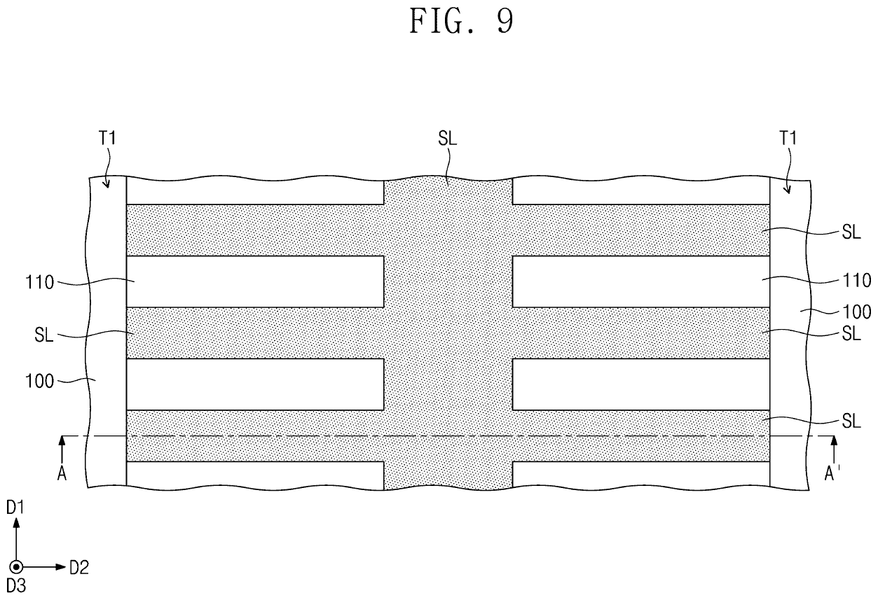

FIG. 8, which is a diagram illustrating a semiconductor device according to some embodiments of the inventive concept, is an enlarged view of a portion of the peripheral structure of FIG. 5. For conciseness, differences from the semiconductor device described above with reference to FIGS. 4 to 7 will be mainly described.

Referring to FIGS. 5 and 8, according to some embodiments, the lower doping region LDP may be disposed adjacent to the second surface 300b of the substrate 300 and may be locally disposed in the substrate 300 between the first well region 302 and the second well region 303. That is, the lower doping region LDP may not extend into the first well region 302 and the second well region 303.

The semiconductor device according to the present embodiments is substantially the same as the semiconductor device described above with reference to FIGS. 4 to 7 except for the above-mentioned differences.

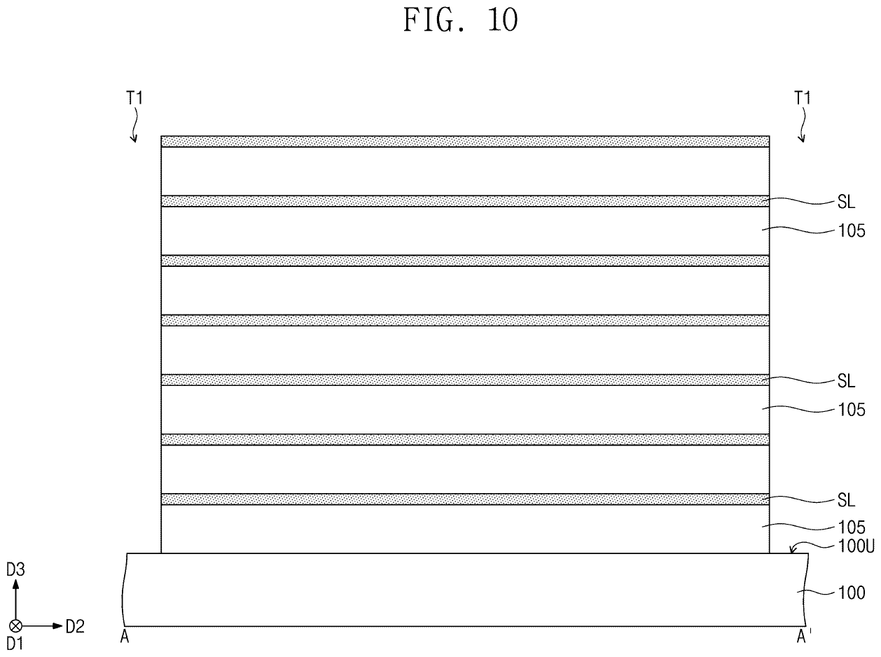

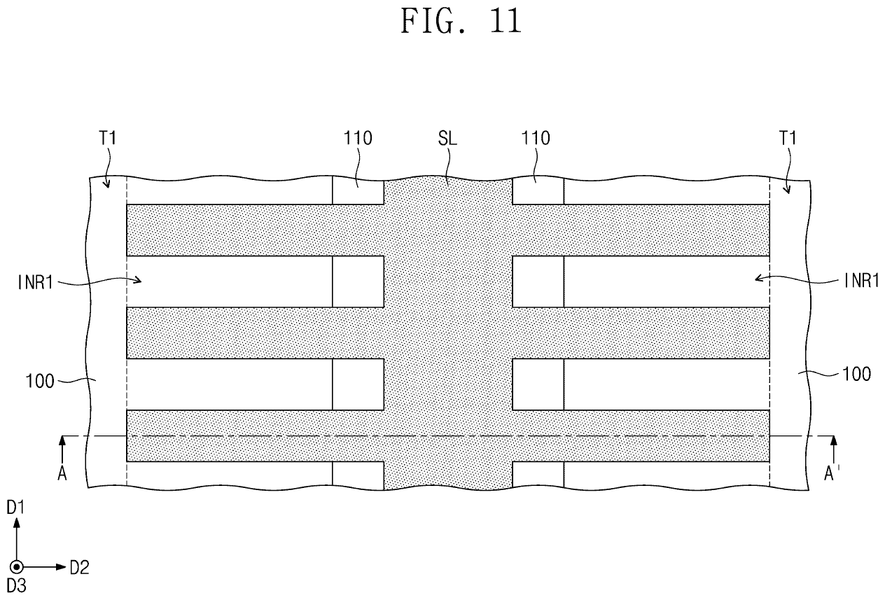

FIGS. 9, 11, 13, 15, 17, 19, and 21 are plan views illustrating a method for manufacturing a semiconductor device according to some embodiments of the inventive concept. FIGS. 10, 12, 14, 16, 18, 20, and 22 are cross-sectional views taken along line A-A′ of FIGS. 9, 11, 13, 15, 17, 19, and 21, respectively. For conciseness, descriptions overlapping with the above descriptions of the semiconductor device provided with FIGS. 4 to 7 will not be provided.

Referring to FIGS. 9 and 10, sacrificial layers 105 and semiconductor layers SL may be alternately stacked on the lower substrate 100. The sacrificial layers 105 and the semiconductor layers SL may include a semiconductor material, and the sacrificial layers 105 may include a material having etch selectivity for the semiconductor layers SL. The semiconductor layers SL may include one of silicon (Si), germanium (Ge), or silicon-germanium (SiGe). The sacrificial layers 105 may include one of silicon (Si), germanium (Ge), or silicon-germanium (SiGe) differing from that of the semiconductor layers SL. For example, the semiconductor layers SL may include silicon (Si), and the sacrificial layers 105 may include silicon-germanium (SiGe). The sacrificial layers 105 and the semiconductor layers SL may each have a thickness in the third direction D3, and the thickness of each of the sacrificial layers 105 may be larger than the thickness of each of the semiconductor layers SL. The lowermost sacrificial layer 105 among the sacrificial layers 105 may be interposed between the lowermost semiconductor layer SL among the semiconductor layers SL and the lower substrate 100. The uppermost semiconductor layer SL among the semiconductor layers SL may be disposed on the uppermost sacrificial layer 105 among the sacrificial layers 105.

First filling patterns 110 may be formed in the sacrificial layers 105 and the semiconductor layers SL. The first filling patterns 110 may be spaced apart from each other in the first direction D1 and the second direction D2, and may each penetrate the sacrificial layers 105 and the semiconductor layers SL in the third direction D3. The sacrificial layers 105 and the semiconductor layers SL may extend lengthily in the first direction D1 between the first filling patterns 110 spaced apart from each other in the second direction D2, and may extend lengthily in the second direction D2 between the first filling patterns 110 spaced apart from each other in the first direction D1. The first filling patterns 110 may include an insulating material such as silicon oxide, silicon nitride, and/or silicon oxynitride.

First trenches T1 may be formed so as to penetrate the sacrificial layers 105, the semiconductor layers SL, and the first filling patterns 110. The first trenches T1 may extend in the first direction D1 and may be spaced apart from each other in the second direction D2. The first trenches T1 may each extend in the third direction D3, penetrate the sacrificial layers 105, the semiconductor layers SL, and the first filling patterns 110, and expose the upper surface 100U of the lower substrate 100. Remainders of the sacrificial layers 105, the semiconductor layers SL, and the first filling patterns 110 may be arranged between the first trenches T1. The first trenches T1 may each expose side surfaces of the sacrificial layers 105, the semiconductor layers SL, and the first filling patterns 110.

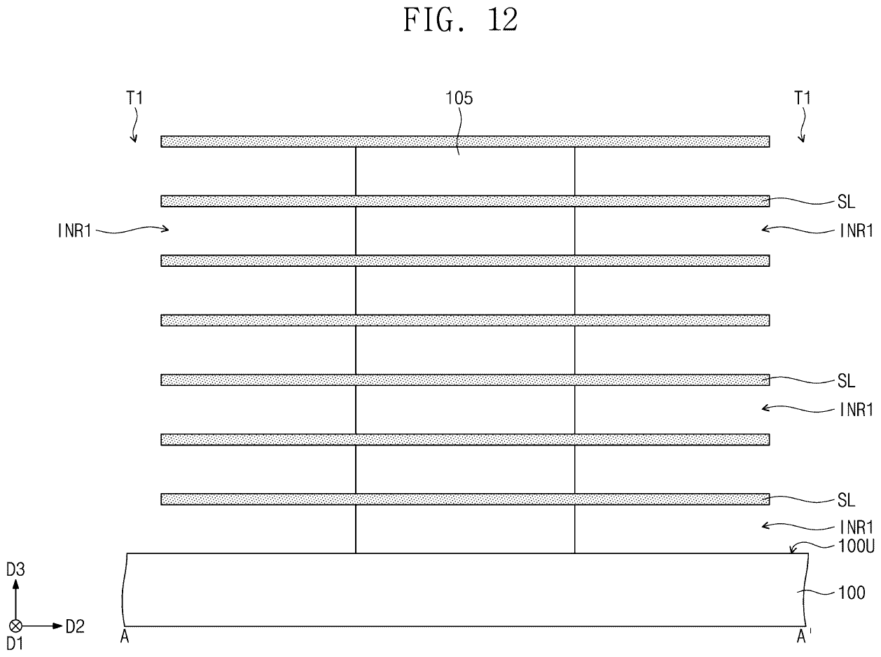

Referring to FIGS. 11 and 12, the side surfaces of the sacrificial layers 105 and the first filling patterns 110 exposed by the first trenches T1 may be laterally recessed. Accordingly, first recess regions INR1 may be formed. The first recess regions INR1 may be interposed between the semiconductor layers SL spaced apart from each other in the third direction D3, and may extend between the semiconductor layers SL spaced apart from each other in the first direction D1. The lowermost first recess region INR1 among the first recess regions INR1 may be interposed between the lowermost semiconductor layer SL among the semiconductor layers SL and the lower substrate 100, and may expose the upper surface 100U of the lower substrate 100.

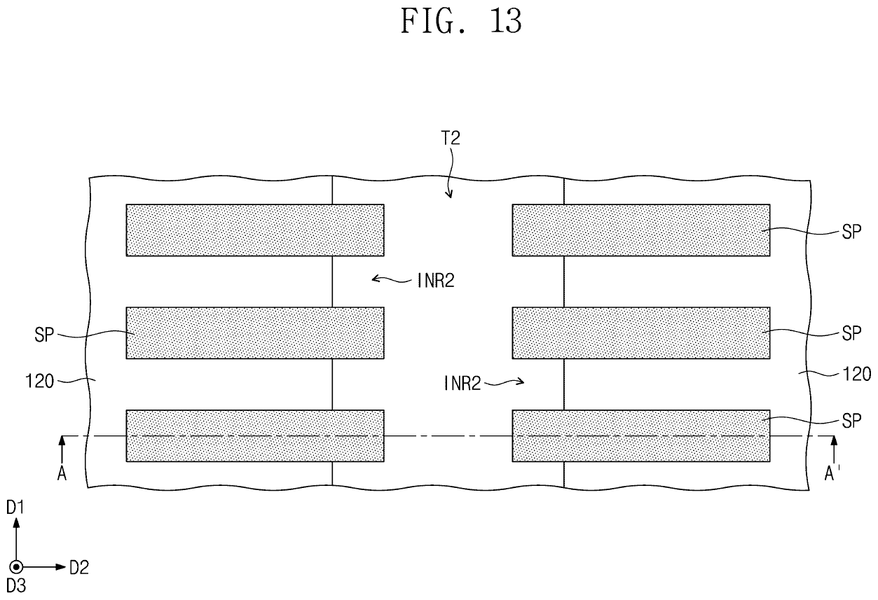

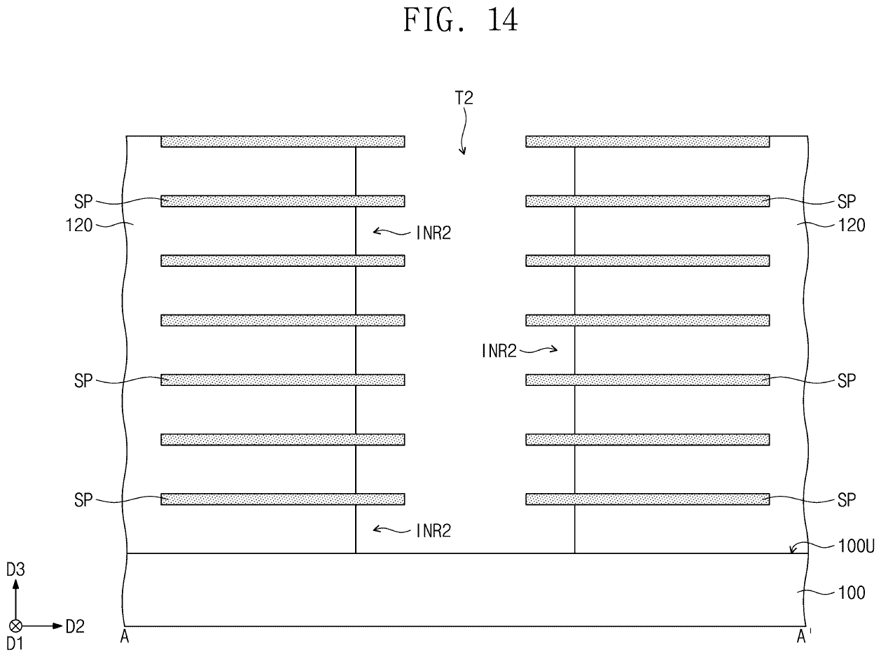

Referring to FIGS. 13 and 14, second filling patterns 120 may be formed so as to fill the first recess regions INR1 and the first trenches T1. The second filling patterns 120 may include an insulating material such as silicon oxide, silicon nitride, and/or silicon oxynitride.

A second trench T2 may be formed so as to penetrate the sacrificial layers 105 and the semiconductor layers SL. The second trench T2 may extend in the first direction D1 and the third direction D3 and expose the upper surface 100U of the lower substrate 100. The semiconductor layers SL may be separated by the second trench T2 into a plurality of semiconductor patterns SP spaced apart from each other in the first direction D1, the second direction D2, and the third direction D3. The semiconductor patterns SP may each have a bar shape extending in the second direction D2. The second trench T2 may expose side surfaces of the sacrificial layers 105 and the first filling patterns 110.

Remainders of the sacrificial layers 105 and the first filling patterns 110 may be removed by laterally recessing the side surfaces of the sacrificial layers 105 and the first filling patterns 110 exposed by the second trench T2. Accordingly, second recess regions INR2 may be formed. The second recess regions INR2 may be interposed between the semiconductor layers SL spaced apart from each other in the third direction D3, and may extend between the semiconductor layers SL spaced apart from each other in the first direction D1. The lowermost second recess region INR2 among the second recess regions INR2 may be interposed between the lowermost semiconductor patterns SP among the semiconductor patterns SP and the lower substrate 100, and may expose the upper surface 100U of the lower substrate 100. The second recess regions INR2 may expose side surfaces of the second filling patterns 120.

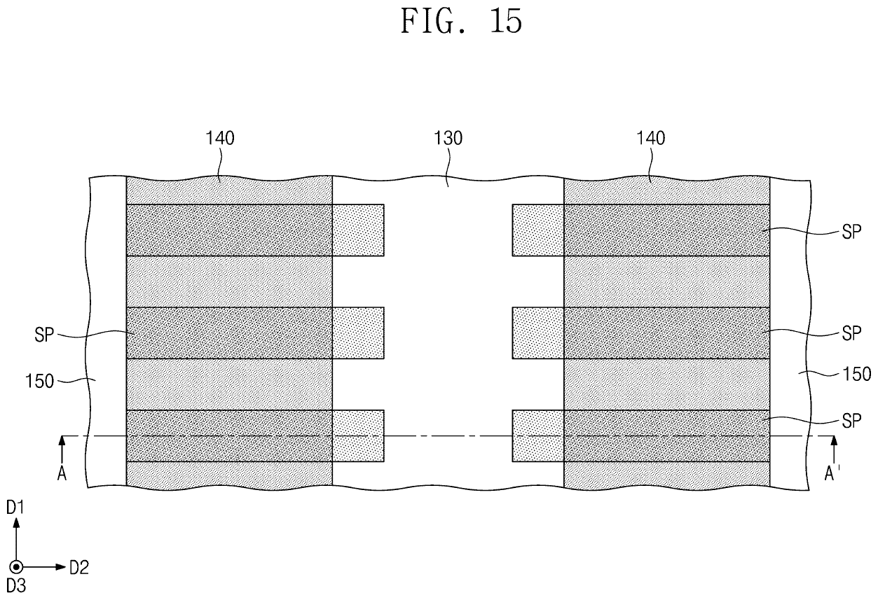

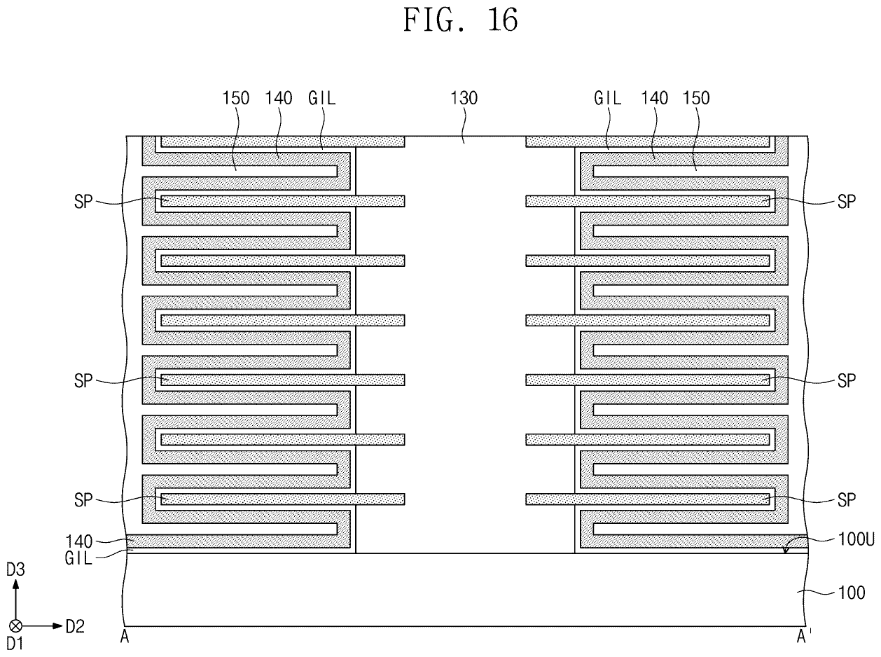

Referring to FIGS. 15 and 16, a third filling pattern 130 may be formed so as to fill the second trench T2 and the second recess regions INR2. The third filling pattern 130 may include an insulating material such as silicon oxide, silicon nitride, and/or silicon oxynitride. Thereafter, the second filling patterns 120 may be removed, and a portion of each of the semiconductor patterns SP may be exposed.

A preliminary gate insulating layer GIL may be formed so as to conformally cover the exposed portions of the semiconductor patterns SP. The preliminary gate insulating layer GIL may extend so as to conformally cover a side surface of the third filling pattern 130 between the semiconductor patterns SP, a side surface of the third filling pattern 130 between the lowermost semiconductor patterns SP among the semiconductor patterns SP and the lower substrate 100, and the upper surface 100U of the lower substrate 100.

A capping insulating layer 140 may be formed on the preliminary gate insulating layer GIL so as to conformally cover the exposed portions of the semiconductor patterns SP. The capping insulating layer 140 may extend so as to conformally cover a side surface of the third filling pattern 130 between the semiconductor patterns SP, a side surface of the third filling pattern 130 between the lowermost semiconductor patterns SP among the semiconductor patterns SP and the lower substrate 100, and the upper surface 100U of the lower substrate 100. The preliminary gate insulating layer GIL may be interposed between the exposed portions of the semiconductor patterns SP and the capping insulating layer 140, between side surfaces of the third filling pattern 130 and the capping insulating layer 140, and between the upper surface 100U of the lower substrate 100 and the capping insulating layer 140.

A mold insulating layer 150 may be formed so as to cover the exposed portions of the semiconductor patterns SP. The mold insulating layer 150 may extend in the second direction D2 between the exposed portions of the semiconductor patterns SP, and may extend in the second direction D2 between the lowermost semiconductor patterns SP among the semiconductor patterns SP and the lower substrate 100. The preliminary gate insulating layer GIL and the capping insulating layer 140 may be interposed between the exposed portions of the semiconductor patterns SP and the mold insulating layer 150, between side surfaces of the third filling pattern 130 and the mold insulating layer 150, and between the upper surface 100U of the lower substrate 100 and the mold insulating layer 150.

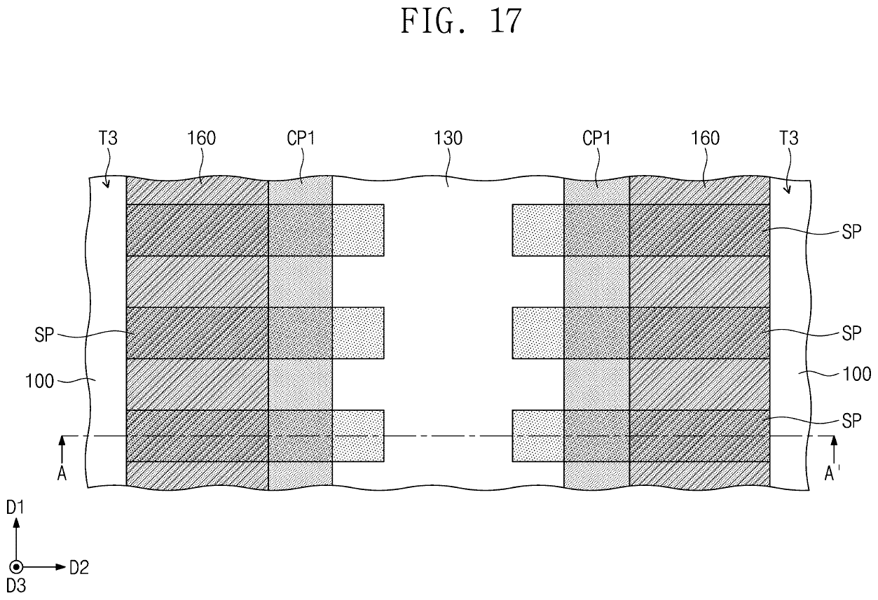

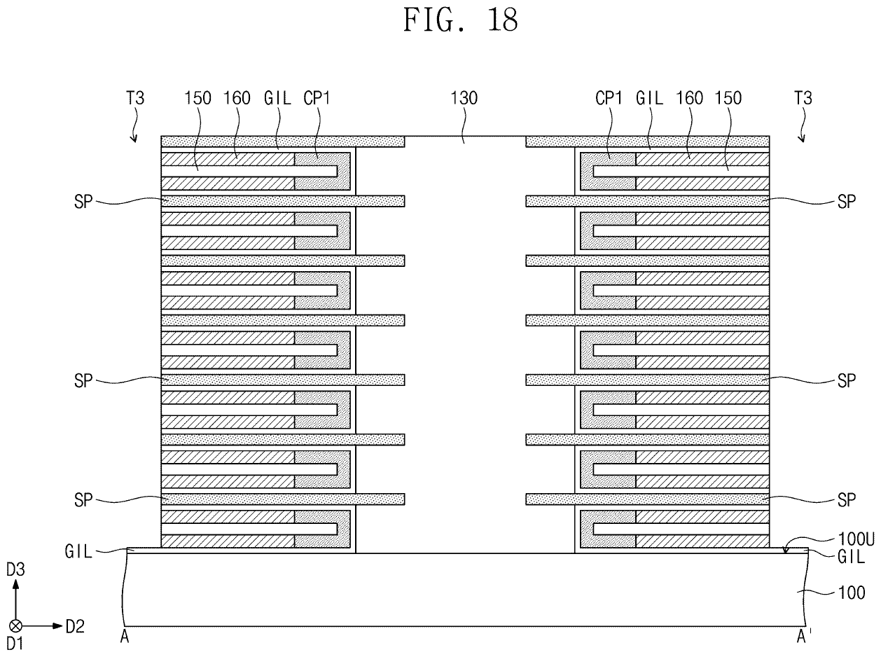

Referring to FIGS. 17 and 18, third trenches T3 may be formed so as to penetrate the mold insulating layer 150. The third trenches T3 may extend in the first direction D1 and may be spaced apart from each other in the second direction D2. The third trenches T3 may each extend in the third direction D3 and expose the preliminary gate insulating layer GIL on the upper surface 100U of the lower substrate 100. The third trenches T3 may each expose side surfaces of the semiconductor patterns SP, the preliminary gate insulating layer GIL, the capping insulating layer 140, and the mold insulating layer 150. The semiconductor patterns SP, remainders of the preliminary gate insulating layer GIL, remainders of the capping insulating layer 140, remainders of the mold insulating layer 150, and the third filling pattern 130 may be arranged between the third trenches T3. The remainders of the mold insulating layer 150 may be referred to as mold patterns 150. The mold patterns 150 may extend between the semiconductor patterns SP in the first direction D1 and the second direction D2.

Side surfaces of the capping insulating layer 140 exposed by each of the third trenches T3 may be laterally recessed. Accordingly, a first capping pattern CP1 may be formed. The first capping pattern CP1 may extend in the first direction D1 and surround a portion of each of the semiconductor patterns SP. The first capping pattern CP1 may extend between side surfaces of the third filling pattern 130 and the mold patterns 150.

Since side surfaces of the capping insulating layer 140 are laterally recessed, empty regions may be formed, and a conductive layer 160 may be formed so as to fill the empty regions. Forming the conductive layer 160 may include forming the conductive layer 160 that fills the empty regions and a portion of each of the third trenches T3 and removing the conductive layer 160 in each of the third trenches T3. The third trenches T3 may each expose side surfaces of the semiconductor patterns SP, the preliminary gate insulating layer GIL, the conductive layer 160, and the mold patterns 150.

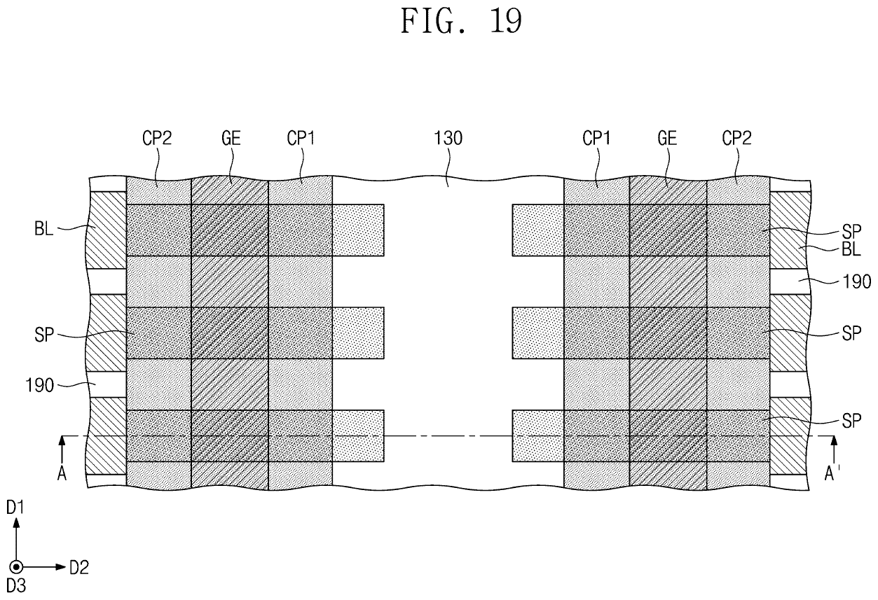

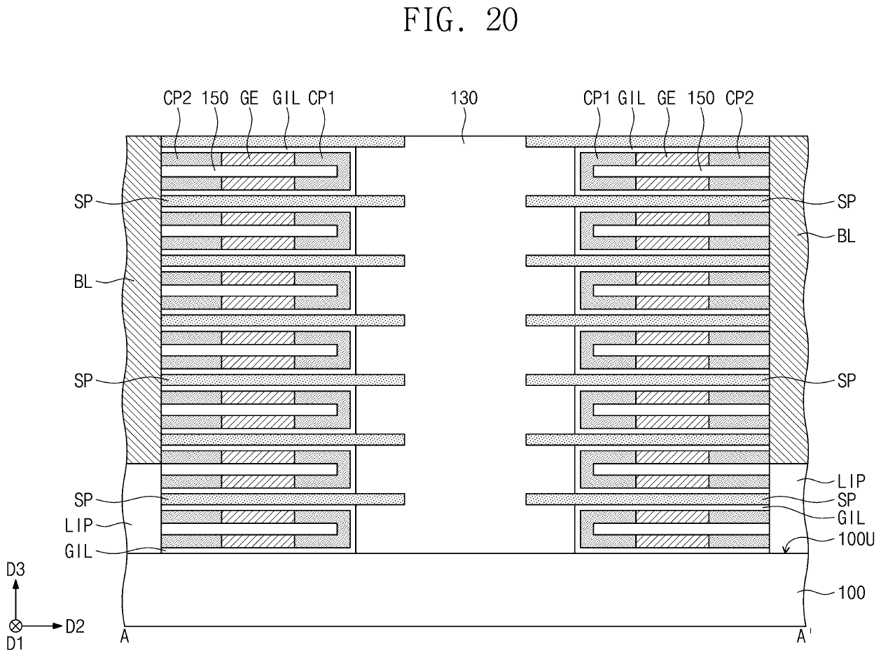

Referring to FIGS. 19 and 20, side surfaces of the conductive layer 160 exposed by each of the third trenches T3 may be laterally recessed. Accordingly, a gate electrode GE may be formed. The gate electrode GE may extend in the first direction D1 and surround the corresponding semiconductor pattern SP among the semiconductor patterns SP. A second capping pattern CP2 may be formed so as to fill remainders of the empty regions. The second capping pattern CP2 may extend in the first direction D1 and surround a portion of each of the semiconductor patterns SP.

The preliminary gate insulating layer GIL may be interposed between each of the semiconductor patterns SP and the gate electrode GE, and may extend between each of the semiconductor patterns SP and the first capping pattern CP1 and between each of the semiconductor patterns SP and the second capping pattern CP2. The preliminary gate insulating layer GIL may further extend between side surfaces of the third filling pattern 130 and the first capping pattern CP1.

A buried insulating layer 190 may be formed so as to fill each of the third trenches T3. Forming the buried insulating layer 190 may include, for example, removing a portion of the preliminary gate insulating layer GIL exposed by each of the third trenches T3 from the upper surface 100U of the lower substrate 100, and forming the buried insulating layer 190 filling each of the third trenches T3.

Lower insulating patterns LIP and bit lines BL may be formed so as to penetrate the buried insulating layer 190. The lower insulating patterns LIP may be spaced apart from each other in the first direction D1, and the lower insulating patterns LIP may each penetrate a lower portion of the buried insulating layer 190 in the third direction D3. The bit lines BL may be respectively formed on the lower insulating patterns LIP. The bit lines BL may be spaced apart from each other in the first direction D1, and may each penetrate an upper portion of the buried insulating layer 190 in the third direction D3.

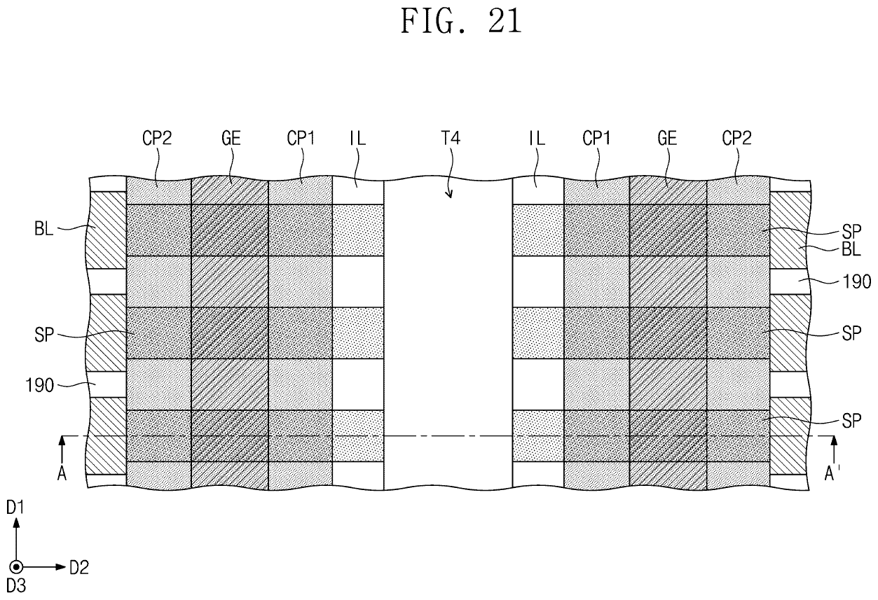

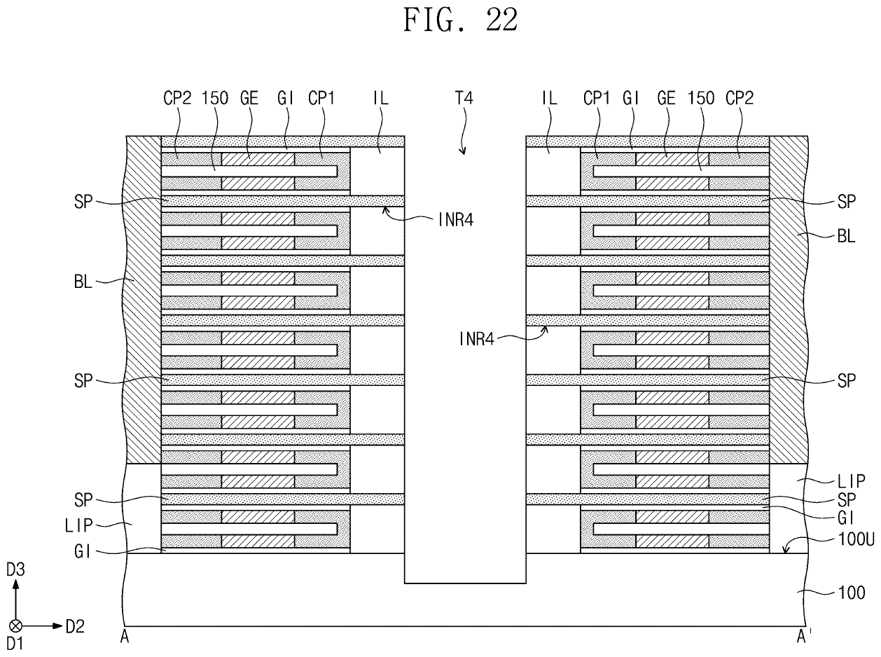

Referring to FIGS. 21 and 22, a fourth trench T4 may be formed so as to penetrate the third filling pattern 130. The fourth trench T4 may extend in the first direction D1 and extend in the third direction D3 so as to expose the upper surface 100U of the lower substrate 100. According to some embodiments, the fourth trench T4 may extend into the substrate 100 in the third direction D3.

The fourth trench T4 may expose side surfaces of remainders of the third filling pattern 130 between the semiconductor patterns SP. The remainders of the third filling pattern 130 exposed by the fourth trench T4 may be removed, and thus fourth recess regions INR4 may be formed between the semiconductor patterns SP. While the fourth recess regions INR4 are being formed, a portion of the preliminary gate insulating layer GIL may also be removed. Accordingly, the fourth recess regions INR4 may each expose a side surface of the first capping pattern CP1. A remainder of the preliminary gate insulating layer GIL may be referred to as a gate insulating layer GI.

An insulating layer IL may be formed so as to fill each of the fourth recess regions INR4. Forming the insulating layer IL may include, for example, forming the insulating layer IL that fills each of the fourth recess regions INR4 and at least a portion of the fourth trench T4 and removing the insulating layer IL in the fourth trench T4. The insulating layer IL may surround an end portion of each of the semiconductor patterns SP. The fourth trench T4 may expose side surfaces of the end portions of the semiconductor patterns SP.

Referring back to FIGS. 4 and 5, the exposed side surfaces of the end portions of the semiconductor patterns SP may be laterally recessed, and thus empty regions exposing the semiconductor patterns SP may be formed in the insulating layer IL. A plurality of storage electrodes SE may be formed so as to respectively fill the empty regions. A side surface of the insulating layer IL exposed by the fourth trench T4 may be laterally recessed, and thus upper surfaces and lower surfaces of the plurality of storage electrodes SE may be exposed. A dielectric layer 200 may be formed so as to conformally cover side surfaces, upper surfaces, and lower surfaces of the plurality of storage electrodes SE. A remainder of the insulating layer IL may remain between the first capping pattern CP1 and the dielectric layer 200. A plate electrode PE may be formed so as to fill the fourth trench T4. The plate electrode PE may extend to a space between the plurality of storage electrodes SE, and the dielectric layer 200 may be interposed between each of the plurality of storage electrodes SE and the plate electrode PE. The plurality of storage electrodes SE, the dielectric layer 200, and the plate electrode PE may constitute a data storage pattern DSP. The data storage pattern DSP may be a capacitor, for example.

The semiconductor patterns SP, the gate electrodes GE, the first and second capping patterns CP1 and CP2, the gate insulating layer GI, the mold patterns 150, the lower insulating patterns LIP, the bit lines BL, the buried insulating layer 190, the plurality of storage electrodes SE, the dielectric layer 200, and the insulating layer IL may be referred to as a stack structure SS.

A first cell insulating layer 210 may be formed on the stack structure SS and the plate electrode PE and cover the stack structure SS and the plate electrode PE. First cell conductive patterns 220 may be formed in the first cell insulating layer 210. The first cell conductive patterns 220 may each penetrate the first cell insulating layer 210 in the third direction D3, and may be connected to the bit lines BL and the plate electrode PE.

A second cell insulating layer 230 may be formed on the first cell insulating layer 210 and cover the first cell conductive patterns 220. Second cell conductive patterns 240 may be formed in the second cell insulating layer 230. The first cell conductive patterns 220 may be connected to the corresponding second cell conductive patterns 240 among the second cell conductive patterns 240. Cell bonding pads 250 may be formed in the second cell insulating layer 230 and on the second cell conductive patterns 240. The cell bonding pads 250 may be connected to the corresponding second cell conductive patterns 240 among the second cell conductive patterns 240. The cell bonding pads 250 may be electrically connected to the first cell conductive patterns 220 through the second cell conductive patterns 240.

The stack structure SS, the plate electrode PE, the first cell insulating layer 210, the first cell conductive patterns 220, the second cell insulating layer 230, the second cell conductive patterns 240, and the cell bonding pads 250 may be referred to as a cell array structure CS.

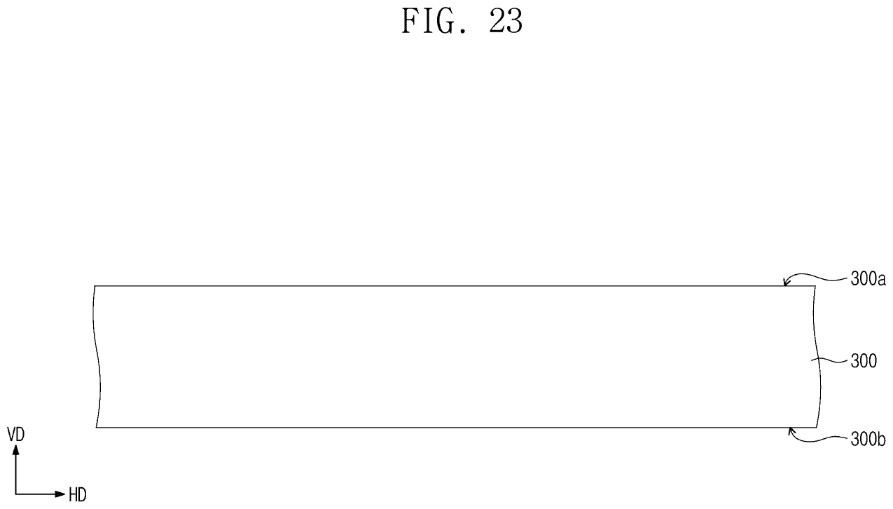

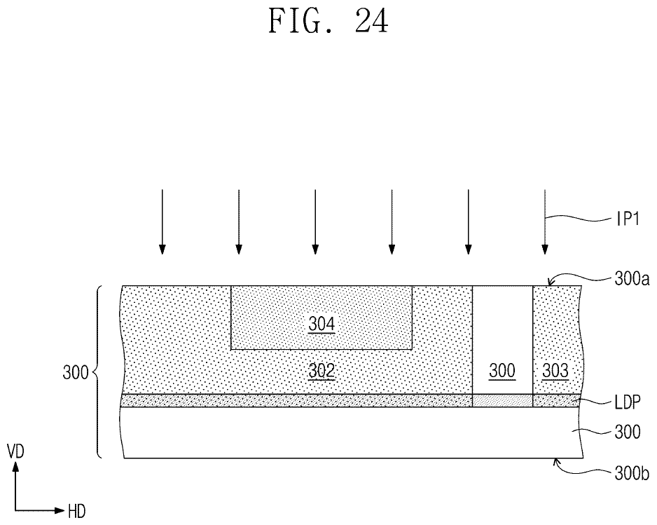

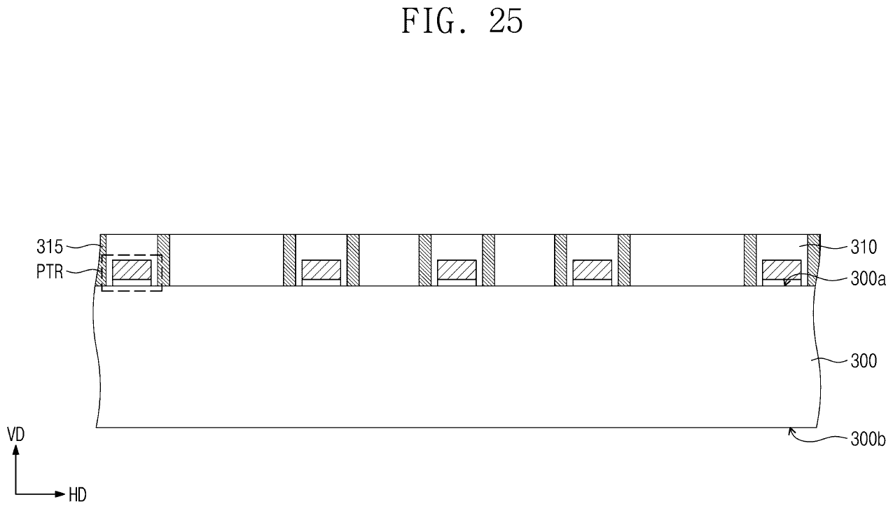

FIGS. 23, 25, and 27 are cross-sectional views illustrating a method for manufacturing a semiconductor device according to some embodiments of the inventive concept, and FIGS. 24, 26, and 28 are enlarged views of portions of FIGS. 23, 25, and 27, respectively. For conciseness, descriptions overlapping with the above descriptions of the semiconductor device provided with FIGS. 4 to 7 will not be provided.

Referring to FIGS. 23 and 24, a substrate 300 having a first surface 300a and a second surface 300b opposite to each other may be provided. A first well region 302 and a second well region 303 may be formed in the substrate 300 and may be spaced apart from each other in the horizontal direction HD parallel to the first surface 300a and the second surface 300b of the substrate 300. A portion of the substrate 300 may be interposed between the first well region 302 and the second well region 303. The first well region 302 and the second well region 303 may extend from the first surface 300a of the substrate 300 toward the second surface 300b of the substrate 300. The substrate 300 may have a first conductive type, and the first well region 302 and the second well region 303 may have a second conductive type different from the first conductive type. The substrate 300 may include a first dopant having the first conductive type, and the first well region 302 and the second well region 303 may include a second dopant having the second conductive type. Forming the first well region 302 and the second well region 303 may include, for example, performing an ion injection process for injecting the second dopant into the substrate 300.

A third well region 304 may be formed in the first well region 302 and may extend from the first surface 300a of the substrate 300 into the first well region 302. The third well region 304 may have the same conductive type (e.g., the first conductive type) as the substrate 300. The third well region 304 may include the first dopant having the first conductive type. Forming the third well region 304 may include, for example, performing an ion injection process for injecting the first dopant into the first well region 302.

A lower doping region LDP may be formed in the substrate 300 between the first well region 302 and the second well region 303. The lower doping region LDP may be spaced apart from the first surface 300a of the substrate 300 in the vertical direction VD perpendicular to the first surface 300a and the second surface 300b of the substrate 300. The lower doping region LDP may be formed in the substrate 300 between a lower portion of the first well region 302 and a lower portion of the second well region 303.

According to some embodiments, the lower doping region LDP may extend into the lower portion of the first well region 302 and the lower portion of the second well region 303 in the horizontal direction HD. According to other embodiments, the lower doping region LDP may be locally formed in the substrate 300 between the lower portion of the first well region 302 and the lower portion of the second well region 303, as described above with reference to FIG. 8.

The lower doping region LDP may have the same conductive type (e.g., the first conductive type) as the substrate 300, and may include the first dopant having the first conductive type. The concentration of the first dopant in the lower doping region LDP may be higher than the concentration of the first dopant in the substrate 300.

Forming the lower doping region LDP may include performing a first ion injection process IP1 on the first surface 300a of the substrate 300. According to some embodiments, the first ion injection process IP1 may include injecting the first dopant into the lower portion of the first well region 302, the lower portion of the second well region 303, and the substrate 300 between the lower portion of the first well region 302 and the lower portion of the second well region 303. According to other embodiments, the first ion injection process IP1 may include locally injecting the first dopant into the substrate 300 between the lower portion of the first well region 302 and the lower portion of the second well region 303.

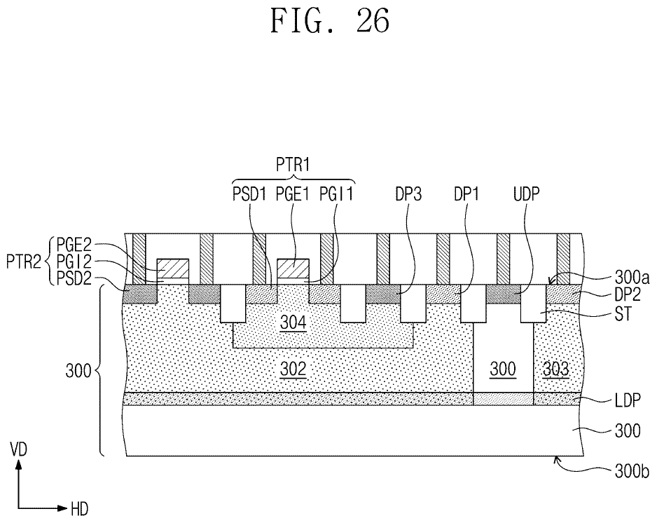

Referring to FIGS. 25 and 26, the device isolation patterns ST may be formed in the substrate 300 and arranged adjacent to the first surface 300a of the substrate 300. Forming the device isolation patterns ST may include, for example, forming trenches extending from the first surface 300a of the substrate 300 into the substrate 300 and forming an insulating layer filling the trenches.

The upper doping region UDP may be formed in the substrate 300 between the first well region 302 and the second well region 303 and may be adjacent to the first surface 300a of the substrate 300. The upper doping region UDP may be spaced apart from the lower doping region LDP in the vertical direction VD. A portion of the substrate 300 may be interposed between the upper doping region UDP and the lower doping region LDP. The upper doping region UDP may have the same conductive type (e.g., the first conductive type) as the substrate 300, and may include the first dopant having the first conductive type. The concentration of the first dopant in the upper doping region UDP may be higher than the concentration of the first dopant in the substrate 300. Forming the upper doping region UDP may include, for example, performing an ion injection process for injecting the first dopant into the substrate 300 between the first well region 302 and the second well region 303 and a region adjacent to the first surface 300a of the substrate 300.

A first doping region DP1 may be formed in the first well region 302 and may be adjacent to the first surface 300a of the substrate 300. A second doping region DP2 may be formed in the second well region 303 and may be adjacent to the first surface 300a of the substrate 300. The first doping region DP1 may have the same conductive type (e.g., the second conductive type) as the first well region 302, and the second doping region DP2 may have the same conductive type (e.g., the second conductive type) as the second well region 303. The first doping region DP1 and the second doping region DP2 may include the second dopant having the second conductive type. A concentration of the second dopant in the first doping region DP1 may be higher than a concentration of the second dopant in the first well region 302. A concentration of the second dopant in the second doping region DP2 may be higher than a concentration of the second dopant in the second well region 303. The upper doping region UDP may be disposed between the first doping region DP1 and the second doping region DP2. The corresponding device isolation patterns ST among the device isolation patterns ST may be interposed between the upper doping region UDP and the first doping region DP1 and between the upper doping region UDP and the second doping region DP2, and may extend between the first well region 302 and the substrate 300 and between the second well region 303 and the substrate 300. Forming the first doping region DP1 and the second doping region DP2 may include, for example, performing an ion injection process for injecting the second dopant into the first well region 302 and the second well region 303 and a region adjacent to the first surface 300a of the substrate 300.

A third doping region DP3 may be formed in the third well region 304 and may be adjacent to the first surface 300a of the substrate 300. The third doping region DP3 may have the same conductive type (e.g., the first conductive type) as the third well region 304. The third doping region DP3 may include the first dopant having the first conductive type. A concentration of the first dopant in the third doping region DP3 may be higher than a concentration of the first dopant in the third well region 304. Forming the third doping region DP3 may include, for example, performing an ion injection process for injecting the first dopant into the third well region 304 and a region adjacent to the first surface 300a of the substrate 300. The corresponding device isolation pattern ST among the device isolation patterns ST may be interposed between the first doping region DP1 and the third doping region DP3 and may extend between the first well region 302 and the third well region 304.

Peripheral transistors PTR may be formed on the first surface 300a of the substrate 300. The peripheral transistors PTR may include a first peripheral transistor PTR1 disposed on the third well region 304 and a second peripheral transistor PTR2 disposed on the first well region 302. The first peripheral transistor PTR1 may be spaced apart from the third doping region DP3 in the horizontal direction HD. The corresponding device isolation pattern ST among the device isolation patterns ST may be arranged between the first peripheral transistor PTR1 and the third doping region DP3 and may extend into the third well region 304. The second peripheral transistor PTR2 may be spaced apart from the first peripheral transistor PTR1, the third well region 304, the third doping region DP3, and the first doping region DP1 in the horizontal direction HD. The corresponding device isolation pattern ST among the device isolation patterns ST may be arranged between the first peripheral transistor PTR1 and the second peripheral transistor PTR2 and may extend between the first well region 302 and the third well region 304.

The first peripheral transistor PTR1 may include a first peripheral gate electrode PGE1 on the third well region 304, a first peripheral gate insulating pattern PGI1 between the third well region 304 and the first peripheral gate electrode PGE1, and first peripheral source/drain regions PSD1 arranged on both sides of the first peripheral gate electrode PGE1 and in the third well region 304. The first peripheral source/drain regions PSD1 may have a conductive type different from the third well region 304 and have the second conductive type, for example. Forming the first peripheral transistor PTR1 may include, for example, forming the first peripheral gate insulating pattern PGI1 and the first peripheral gate electrode PGE1 sequentially stacked on the third well region 304 and injecting the second dopant having the second conductive type into the third well region 304 on both sides of the first peripheral gate electrode PGE1.

The second peripheral transistor PTR2 may include a second peripheral gate electrode PGE2 on the first well region 302, a second peripheral gate insulating pattern PGI2 between the first well region 302 and the second peripheral gate electrode PGE2, and second peripheral source/drain regions PSD2 arranged on both sides of the second peripheral gate electrode PGE2 and in the first well region 302. The second peripheral source/drain regions PSD2 may have a conductive type different from the first well region 302 and have the first conductive type, for example. Forming the second peripheral transistor PTR2 may include, for example, forming the second peripheral gate insulating pattern PGI2 and the second peripheral gate electrode PGE2 sequentially stacked on the first well region 302 and injecting the first dopant having the first conductive type into the first well region 302 on both sides of the second peripheral gate electrode PGE2.

A first upper insulating layer 310 may be formed on the first surface 300a of the substrate 300 and cover the peripheral transistors PTR. Peripheral conductive contacts 315 may be formed in the first upper insulating layer 310. The peripheral conductive contacts 315 may penetrate the first upper insulating layer 310 in the vertical direction VD and may be respectively connected to the upper doping region UDP, the first to third doping regions DP1 to DP3, the first peripheral source/drain regions PSD1, and the second peripheral source/drain regions PSD2. Forming the peripheral conductive contacts 315 may include, for example, forming vertical holes penetrating the first upper insulating layer 310 in the vertical direction VD and forming a conductive layer filling the vertical holes.

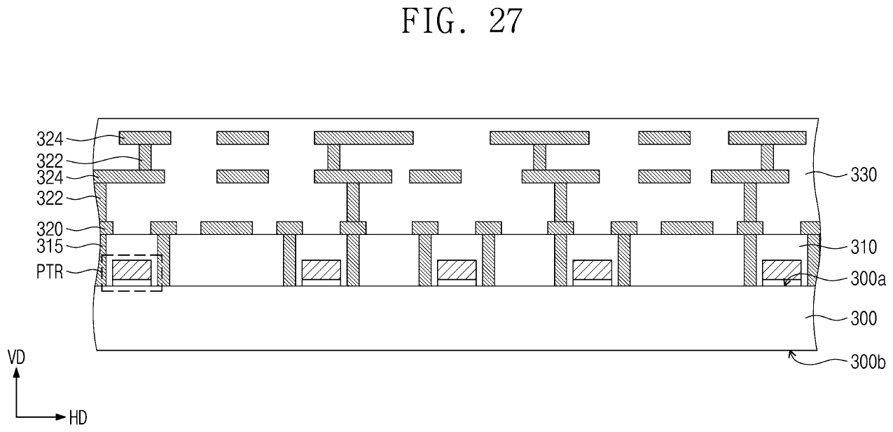

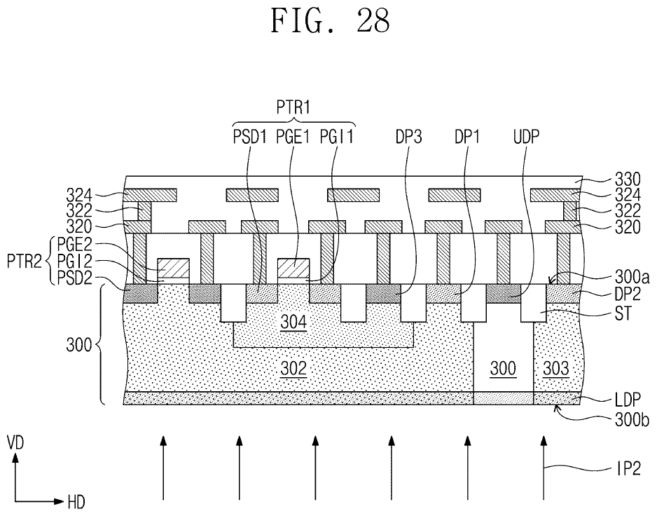

Referring to FIGS. 27 and 28, first wiring lines 320 may be formed on the first upper insulating layer 310 and respectively connected to the peripheral conductive contacts 315. Wiring contacts 322 may be formed on the first wiring lines 320, and second wiring lines 324 may be formed on the wiring contacts 322. The wiring contacts 322 may be arranged between the first wiring lines 320 and the second wiring lines 324 so as to electrically connect the first wiring lines 320 and the second wiring lines 324. The first wiring lines 320, the wiring contacts 322, and the second wiring lines 324 may be referred to as peripheral wiring patterns 320, 322, and 324. A second upper insulating layer 330 may be formed on the first upper insulating layer 310 and cover the peripheral wiring patterns 320, 322, and 324.

A grinding process may be performed on the second surface 300b of the substrate 300, and thus a lower portion of the substrate 300 may be removed. Due to the grinding process, the lower portion of the first well region 302, the lower portion of the second well region 303, and the lower doping region LDP may be arranged adjacent to the second surface 300b of the substrate 300.

Forming the lower doping region LDP may further include performing a second ion injection process IP2 on the second surface 300b of the substrate 300. According to some embodiments, the second ion injection process IP2 may include injecting the first dopant into the lower portion of the first well region 302, the lower portion of the second well region 303, and the substrate 300 between the lower portion of the first well region 302 and the lower portion of the second well region 303. According to other embodiments, the second ion injection process IP2 may include locally injecting the first dopant into the substrate 300 between the lower portion of the first well region 302 and the lower portion of the second well region 303. The lower doping region LDP may be formed through at least one of the first ion injection process IP1 or the second ion injection process IP2.

Referring back to FIGS. 5 and 6, a lower insulating layer 340 may be formed on the second surface 300b of the substrate 300. A vertical conductive pattern 345 may be formed so as to penetrate the substrate 300, the lower insulating layer 340, and the first upper insulating layer 310 in the vertical direction VD (e.g., the third direction D3). A side insulating pattern 347 may be formed between the substrate 300 and the vertical conductive pattern 345. Forming the vertical conductive pattern 345 and the side insulating pattern 347 may include, for example, forming a vertical through-hole penetrating the substrate 300, the lower insulating layer 340, and the first upper insulating layer 310 in the vertical direction VD (e.g., the third direction D3), forming the side insulating pattern 347 conformally covering an inner surface of the vertical through-hole, and forming the vertical conductive pattern 345 filling a remainder of the vertical through-hole. The vertical conductive pattern 345 may be connected to the corresponding first wiring line 320 among the first wiring lines 320.

Peripheral bonding pads 350 may be formed in the lower insulating layer 340, and the lower insulating layer 340 may expose lower surfaces of the peripheral bonding pads 350. The vertical conductive pattern 345 may extend in the vertical direction VD (e.g., the third direction D3) and be respectively connected to the peripheral bonding pads 350.

The substrate 300 including the first to third well regions 302, 303, and 304, the upper doping region UDP, the lower doping region LDP, and the first to third doping regions DP1 to DP3, the peripheral transistors PTR, the first and second upper insulating layers 310 and 330, the peripheral conductive contacts 315, the peripheral wiring patterns 320, 322, and 324, the lower insulating layer 340, the vertical conductive pattern 345, the side insulating pattern 347, and the peripheral bonding pads 350 may be referred to as a peripheral circuit structure PS.

The peripheral circuit structure PS may be provided on the cell array structure CS formed according to FIGS. 9 to 22. According to some embodiments, the peripheral bonding pads 350 of the peripheral circuit structure PS may be in contact with the cell bonding pads 250 of the cell array structure CS, respectively, and the lower insulating layer 340 of the peripheral circuit structure PS may be in contact with the second cell insulating layer 230 of the cell array structure CS. That is, the cell array structure CS and the peripheral circuit structure PS may be coupled using a hybrid bonding method and may be electrically connected to each other through the cell bonding pads 250 and the peripheral bonding pads 350.

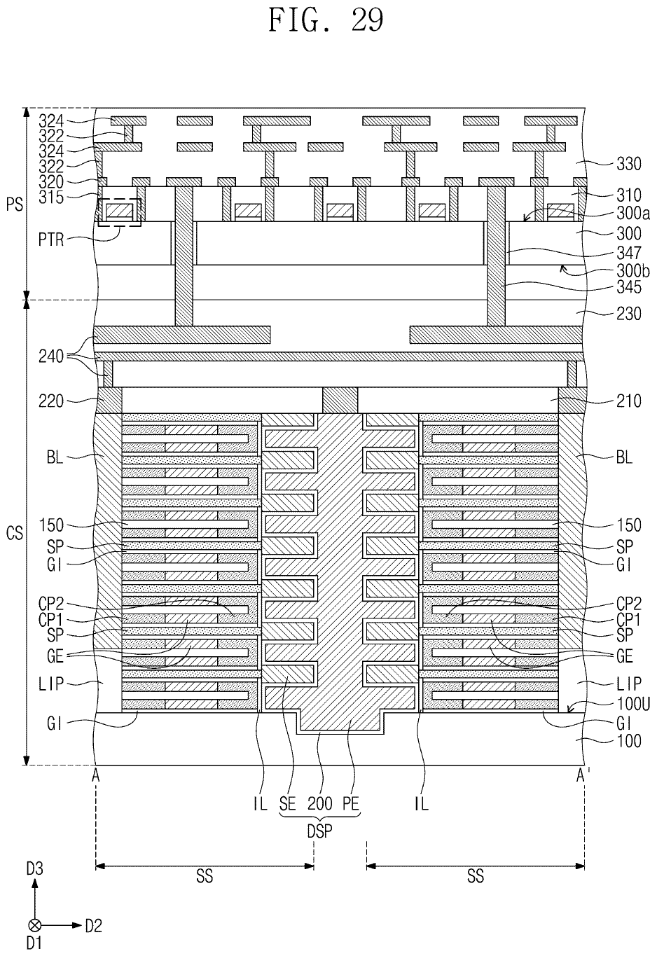

FIG. 29 is a cross-sectional view of a semiconductor device, taken along line A-A′ of FIG. 4, according to some embodiments of the inventive concept. For simple illustration, the peripheral circuit structure of FIG. 29 is omitted in FIG. 4. For conciseness, differences from the semiconductor device described above with reference to FIGS. 4 to 7 will be mainly described.

Referring to FIG. 29, according to some embodiments, the cell array structure CS may not include the cell bonding pads 250, and the peripheral circuit structure PS may not include the peripheral bonding pads 350. The second cell insulating layer 230 of the cell array structure CS may be in contact with the lower insulating layer 340 of the peripheral circuit structure PS, and the cell array structure CS and the peripheral circuit structure PS may be coupled to each other due to the contact between the second cell insulating layer 230 and the lower insulating layer 340.

The vertical conductive pattern 345 of the peripheral circuit structure PS may penetrate the first upper insulating layer 310, the substrate 300, and the lower insulating layer 340 of the peripheral circuit structure PS in the third direction D3, and may extend into the second cell insulating layer 230 of the cell array structure CS in the third direction D3. The vertical conductive pattern 345 of the peripheral circuit structure PS may be connected to the corresponding first wiring line 320 among the first wiring lines 320 of the peripheral circuit structure PS, and may be connected to the corresponding second cell conductive pattern 240 among the second cell conductive patterns 240 of the cell array structure CS. Accordingly, the peripheral circuit structure PS and the cell array structure CS may be electrically connected to each other.

The semiconductor device according to the present embodiments is substantially the same as the semiconductor device described above with reference to FIGS. 4 to 7 except for the above-mentioned differences.

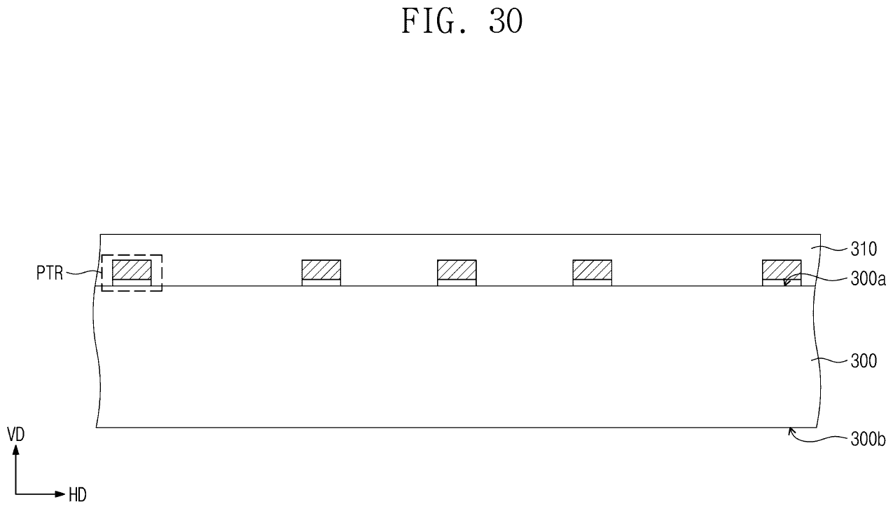

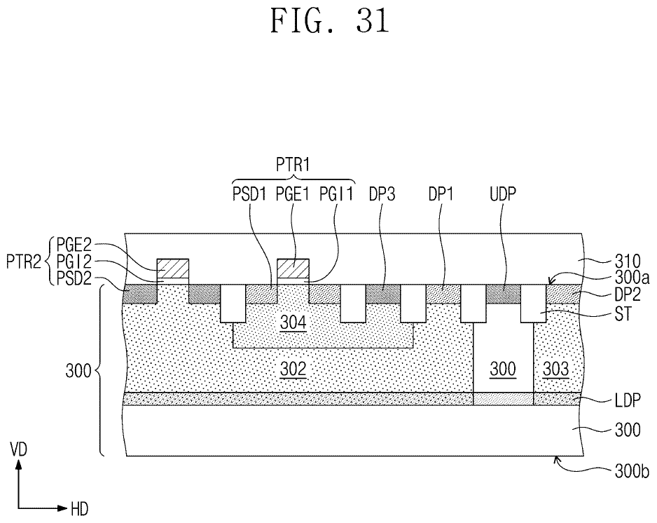

FIGS. 30, 32, and 34 are cross-sectional views illustrating a method for manufacturing a semiconductor device according to some embodiments of the inventive concept, and FIGS. 31, 33, and 35 are enlarged views of portions of FIGS. 30, 32, and 34, respectively. For conciseness, differences from the semiconductor device described with reference to FIGS. 23 to 28 will be mainly described.

Referring to FIGS. 30 and 31, a substrate 300 having a first surface 300a and a second surface 300b opposite to each other may be provided. A first well region 302 and a second well region 303 may be formed in the substrate 300 and may be spaced apart from each other in the horizontal direction HD parallel to the first surface 300a and the second surface 300b of the substrate 300. A third well region 304 may be formed in the first well region 302 and may be adjacent to the first surface 300a of the substrate 300.

A lower doping region LDP and an upper doping region UDP may be formed in the substrate 300 between the first well region 302 and the second well region 303 and may be spaced apart from each other in the vertical direction VD. A first doping region DP1 may be formed in the first well region 302 and may be adjacent to the first surface 300a of the substrate 300. A second doping region DP2 may be formed in the second well region 303 and may be adjacent to the first surface 300a of the substrate 300. A third doping region DP3 may be formed in the third well region 304 and may be adjacent to the first surface 300a of the substrate 300.

Peripheral transistors PTR may be formed on the first surface 300a of the substrate 300. The peripheral transistors PTR may include a first peripheral transistor PTR1 disposed on the third well region 304 and a second peripheral transistor PTR2 disposed on the first well region 302. Device isolation patterns SP may be formed in the substrate 300 and arranged adjacent to the first surface 300a of the substrate 300. A first upper insulating layer 310 may be formed on the first surface 300a of the substrate 300 and cover the peripheral transistors PTR.

The first to third well regions 302, 303, and 304, the lower doping region LDP, the upper doping region UDP, the first to third doping regions DP1 to DP3, the peripheral transistors PTR, the device isolation patterns ST, and the first upper insulating layer 310 may be formed using a method that is substantially the same as the method for forming the first to third well regions 302, 303, and 304, the lower doping region LDP, the upper doping region UDP, the first to third doping regions DP1 to DP3, the peripheral transistors PTR, the device isolation patterns ST, and the first upper insulating layer 310 described above with reference to FIGS. 23 to 28.

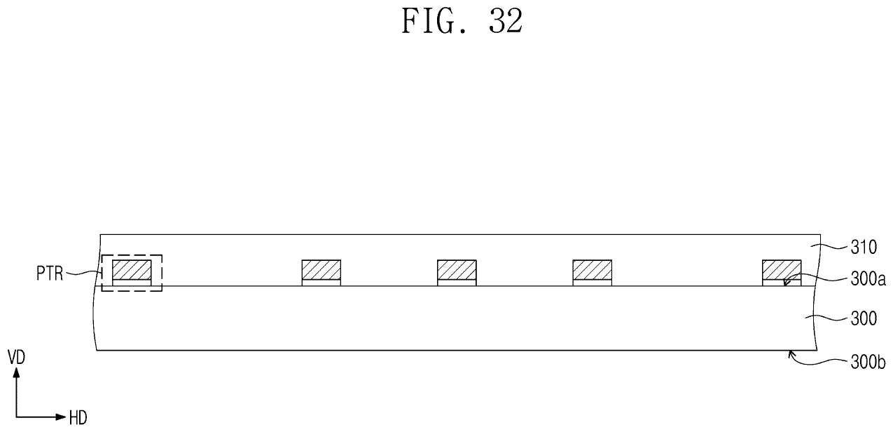

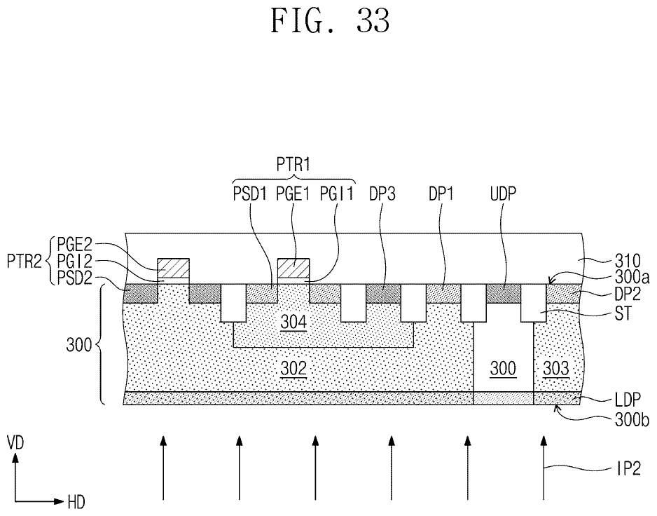

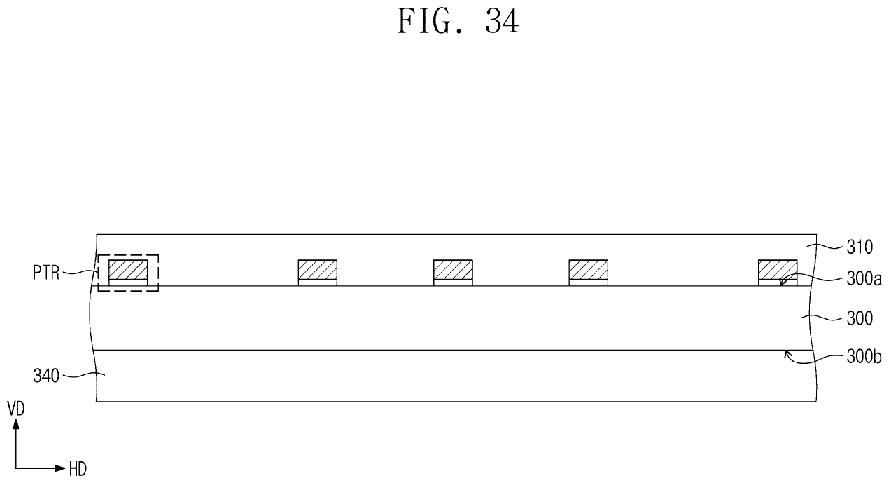

Referring to FIGS. 32 and 33, a grinding process may be performed on the second surface 300b of the substrate 300, and thus a lower portion of the substrate 300 may be removed. Due to the grinding process, a lower portion of the first well region 302, a lower portion of the second well region 303, and the lower doping region LDP may be arranged adjacent to the second surface 300b of the substrate 300. According to some embodiments, the second ion injection process IP2 for forming the lower doping region LDP, described above with reference to FIGS. 23 to 28, may be performed on the second surface 300b of the substrate 300 after the grinding process.

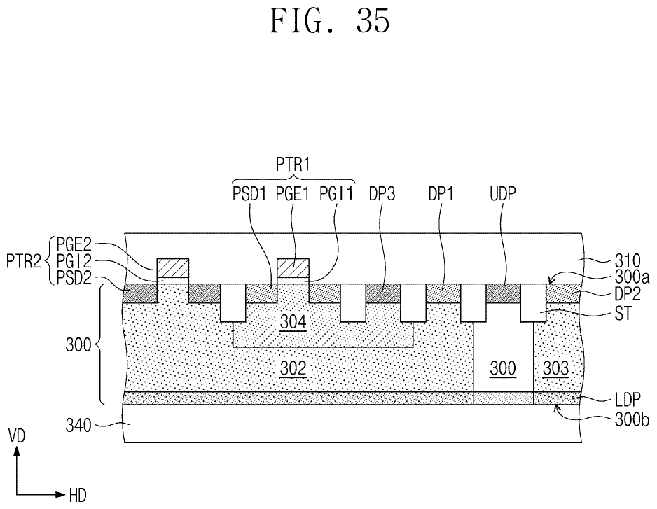

Referring to FIGS. 34 and 35, a lower insulating layer 340 may be formed on the second surface 300b of the substrate 300. The substrate 300 including the first to third well regions 302, 303, and 304, the upper doping region UDP, the lower doping region LDP, and the first to third doping regions DP1 to DP3, the peripheral transistors PTR, the first upper insulating layer 310, and the lower insulating layer 340 may be referred to as a preliminary peripheral circuit structure PS_1.

Referring back to FIG. 29, the preliminary peripheral circuit structure PS_1 may be provided on the cell array structure CS. The cell array structure CS may be formed using a method that is substantially the same as the method described above with reference to FIGS. 9 to 22. The lower insulating layer 340 of the preliminary peripheral circuit structure PS_1 may be in contact with the second cell insulating layer 230 of the cell array structure CS, and the cell array structure CS and the preliminary peripheral circuit structure PS_1 may be coupled to each other due to the contact between the second cell insulating layer 230 and the lower insulating layer 340.

Peripheral conductive contacts 315 may be formed in the first upper insulating layer 310 of the preliminary peripheral circuit structure PS_1. The peripheral conductive contacts 315 may penetrate the first upper insulating layer 310 in the third direction D3 and may be respectively connected to the upper doping region UDP, the first to third doping regions DP1 to DP3, the first peripheral source/drain regions PSD1, and the second peripheral source/drain regions PSD2. The peripheral conductive contacts 315 may be formed using a method that is substantially the same as the method for forming the peripheral conductive contacts 315 described above with reference to FIGS. 23 to 28.

A vertical conductive pattern 345 may be formed so as to penetrate the first upper insulating layer 310, the substrate 300, and the lower insulating layer 340 of the preliminary peripheral circuit structure PS_1 in the third direction D3, and may extend into the second cell insulating layer 230 of the cell array structure CS in the third direction D3. The vertical conductive pattern 345 may be connected to the corresponding second cell conductive pattern 240 among the second cell conductive patterns 240 of the cell array structure CS. A side insulating pattern 347 may be formed between the vertical conductive pattern 345 and the substrate 300. Forming the vertical conductive pattern 345 and the side insulating pattern 347 may include, for example, forming a vertical through-hole penetrating the first upper insulating layer 310, the substrate 300, and the lower insulating layer 340 of the preliminary peripheral circuit structure PS_1 and extending into the second cell insulating layer 230 of the cell array structure CS, forming the side insulating pattern 347 conformally covering an inner surface of the vertical through-hole, and forming the vertical conductive pattern 345 filling a remainder of the vertical through-hole.

First wiring lines 320 may be formed on the first upper insulating layer 310 of the preliminary peripheral circuit structure PS_1 and may be connected to each of the peripheral conductive contacts 315 and the vertical conductive pattern 345. Wiring contacts 322 may be formed on the first wiring lines 320, and second wiring lines 324 may be formed on the wiring contacts 322. The wiring contacts 322 may be arranged between the first wiring lines 320 and the second wiring lines 324 so as to electrically connect the first wiring lines 320 and the second wiring lines 324. The first wiring lines 320, the wiring contacts 322, and the second wiring lines 324 may be referred to as peripheral wiring patterns 320, 322, and 324. A second upper insulating layer 330 may be formed on the first upper insulating layer 310 of the preliminary peripheral circuit structure PS_1 and cover the peripheral wiring patterns 320, 322, and 324.

The substrate 300 including the first to third well regions 302, 303, and 304, the upper doping region UDP, the lower doping region LDP, and the first to third doping regions DP1 to DP3, the peripheral transistors PTR, the first and second upper insulating layers 310 and 330, the peripheral conductive contacts 315, the peripheral wiring patterns 320, 322, and 324, the lower insulating layer 340, the vertical conductive pattern 345, and the side insulating pattern 347 may be referred to as a peripheral circuit structure PS.

In an embodiment of the inventive concept, a method for manufacturing a semiconductor device includes: providing a substrate having a first surface and a second surface opposite to each other; forming, in the substrate, a first well region and a second well region spaced apart from each other in a horizontal direction parallel to the first surface and the second surface of the substrate; and forming, in the substrate between the first well region and the second well region, a lower doping region and an upper doping region spaced apart from each other in a vertical direction perpendicular to the first surface and the second surface of the substrate. The upper doping region may be adjacent to the first surface of the substrate. The substrate, the upper doping region, and the lower doping region may include a first dopant having a first conductive type. A concentration of the first dopant in the lower doping region and a concentration of the first dopant in the upper doping region may be higher than a concentration of the first dopant in the substrate.

According to some embodiments, the first well region and the second well region may have a second conductive type different from the first conductive type.

According to some embodiments, the method may further include performing a grinding process on the second surface of the substrate. After the grinding process, the lower doping region may be adjacent to the second surface of the substrate.

According to some embodiments, the method may further include forming a lower insulating layer on the second surface of the substrate.

According to some embodiments, the method may further include forming a vertical conductive pattern penetrating the substrate and the lower insulating layer in the vertical direction.

According to some embodiments, the forming of the lower doping region may include performing a first ion injection process on the first surface of the substrate before the grinding process.

According to some embodiments, the forming of the lower doping region may include performing a second ion injection process on the second surface of the substrate after the grinding process.

According to some embodiments, the lower doping region may extend into the first well region and the second well region in the horizontal direction.

According to some embodiments, the method may further include: forming peripheral transistors on the first surface of the substrate; and forming a peripheral conductive contact on the first surface of the substrate and on the upper doping region.

According to some embodiments, the method may further include: forming, in the first well region, a first doping region adjacent to the first surface of the substrate; and forming, in the second well region, a second doping region adjacent to the first surface of the substrate. The upper doping region may be disposed between the first doping region and the second doping region. The first well region, the first doping region, the second well region, and the second doping region may include a second dopant having a second conductive type different from the first conductive type. A concentration of the second dopant in the first doping region may be higher than a concentration of the second dopant in the first well region, and a concentration of the second dopant in the second doping region may be higher than a concentration of the second dopant in the second well region.

According to the inventive concept, a peripheral circuit structure may include a substrate having a first surface and a second surface facing each other, peripheral transistors on the first surface of the substrate, and a lower insulating layer on the second surface. The substrate may include a first well region and a second well region that are provided in the substrate and spaced apart from each other in a horizontal direction, and a lower doping region provided in the substrate between the first well region and the second well region and adjacent to the second surface of the substrate. The substrate and the lower doping region may have a first conductive type, and the first and second well regions may have a second conductive type different from the first conductive type. The substrate and the lower doping region may include a first dopant having the first conductive type, and a concentration of the first dopant in the lower doping region may be higher than a concentration of the first dopant in the substrate. Therefore, even if a charge layer (e.g., positive charge) is formed on an interface between the second surface of the substrate and the lower insulating layer, carrier charge (e.g., negative charge) may be suppressed from being induced in the substrate between the first well region and the second well region, and, as a result, electrical isolation between the first well region and the second well region may be improved.

In addition, the peripheral circuit structure may be stacked in a vertical direction on a cell array structure. Since the lower insulating layer of the peripheral circuit structure is in contact with a second cell insulating layer of the cell array structure, the cell array structure and the peripheral circuit structure may be easily bonded to each other.

Therefore, a semiconductor device having improved electrical characteristics and capable of facilitating high integration and a method for manufacturing the same may be provided.

The above descriptions of embodiments of the inventive concept provide examples for describing the inventive concept. Therefore, the inventive concept is not limited to the above embodiments, and it would be obvious that those skilled in the art could make various modifications and changes by combining the above embodiments within the technical spirit of the inventive concept.

What is claimed is:

1. A semiconductor device comprising:
a substrate having a first surface and a second surface opposite to each other;
peripheral transistors disposed on the first surface of the substrate; and
a lower insulating layer disposed on the second surface of the substrate,
wherein the substrate includes:
a first well region and a second well region provided in the substrate and spaced apart from each other in a horizontal direction parallel to the first surface and the second surface of the substrate; and
a lower doping region provided in the substrate between the first well region and the second well region and adjacent to the second surface of the substrate,
wherein the substrate and the lower doping region include a first dopant having a first conductive type,
a concentration of the first dopant in the lower doping region is higher than a concentration of the first dopant in the substrate, and
the first well region and the second well region a second dopant having a second conductive type different from the first conductive type.

2. The semiconductor device of claim 1, further comprising:
a first upper insulating layer disposed on the first surface of the substrate and covering the peripheral transistors;
peripheral wiring patterns disposed on the first upper insulating layer; and
a vertical conductive pattern penetrating the substrate, the first upper insulating layer, and the lower insulating layer in a vertical direction perpendicular to the first surface and the second surface of the substrate and connected to a corresponding peripheral wiring pattern among the peripheral wiring patterns.

3. The semiconductor device of claim 1,
wherein the substrate further includes an upper doping region provided in the substrate between the first well region and the second well region and adjacent to the first surface of the substrate,
wherein the upper doping region includes the first dopant having the first conductive type, and
wherein a concentration of the first dopant in the upper doping region is higher than the concentration of the first dopant in the substrate.

4. The semiconductor device of claim 3,
wherein the substrate further includes a first doping region disposed adjacent to the first surface of the substrate and disposed in the first well region,
wherein the first doping region includes the second dopant having the second conductive type, and
wherein a concentration of the second dopant in the first doping region is higher than a concentration of the second dopant in the first well region.

5. The semiconductor device of claim 4,
wherein the substrate further includes a second doping region disposed adjacent to the first surface of the substrate and disposed in the second well region,
wherein the second doping region includes the second dopant having the second conductive type, and
wherein a concentration of the second dopant in the second doping region is higher than a concentration of the second dopant in the second well region.

6. The semiconductor device of claim 5, further comprising device isolation patterns arranged adjacent to the first surface of the substrate and respectively interposed between the upper doping region and the first doping region and between the upper doping region and the second doping region.

7. The semiconductor device of claim 5,
wherein the substrate further includes:
a third well region disposed adjacent to the first surface of the substrate and disposed in the first well region; and
a third doping region disposed adjacent to the first surface of the substrate and disposed in the third well region,
wherein the third well region and the third doping region include the first dopant having the first conductive type, and
a concentration of the first dopant in the third doping region is higher than a concentration of the first dopant in the third well region.

8. The semiconductor device of claim 7, further comprising device isolation patterns arranged adjacent to the first surface of the substrate and respectively interposed between the upper doping region and the first doping region, between the upper doping region and the second doping region, and between the first doping region and the third doping region.

9. The semiconductor device of claim 7,
wherein the peripheral transistors include a first peripheral transistor disposed on the third well region and spaced apart from the third doping region in the horizontal direction,
wherein the first peripheral transistor includes:
a first peripheral gate electrode disposed on the third well region;
a first peripheral gate insulating pattern disposed between the third well region and the first peripheral gate electrode; and
first peripheral source/drain regions arranged on both sides of the first peripheral gate electrode in the third well region, and
the first peripheral source/drain regions include the second dopant having the second conductive type.

10. The semiconductor device of claim 9,
wherein the peripheral transistors further include a second peripheral transistor disposed on the first well region and spaced apart from the first peripheral transistor, the third well region, the third doping region, and the first doping region in the horizontal direction,
wherein the second peripheral transistor includes:
a second peripheral gate electrode disposed on the first well region;
a second peripheral gate insulating pattern disposed between the first well region and the second peripheral gate electrode; and
second peripheral source/drain regions arranged on both sides of the second peripheral gate electrode in the first well region, and
the second peripheral source/drain regions include the first dopant having the first conductive type.

11. A semiconductor device comprising:
a cell array structure disposed on a lower substrate; and
a peripheral circuit structure disposed on the cell array structure,
wherein the peripheral circuit structure includes:
a substrate having a first surface and a second surface opposite to each other;
peripheral transistors disposed on the first surface of the substrate; and
a lower insulating layer disposed between the second surface of the substrate and the cell array structure,
wherein the substrate includes:
a first well region and a second well region provided in the substrate and spaced apart from each other in a horizontal direction parallel to the first surface and the second surface of the substrate; and
a lower doping region provided in the substrate between the first well region and the second well region and adjacent to the second surface of the substrate,
wherein the substrate and the lower doping region include a first dopant having a first conductive type,
wherein a concentration of the first dopant in the lower doping region is higher than a concentration of the first dopant in the substrate, and
wherein the first well region and the second well region include a second dopant having a second conductive type different from the first conductive type.

12. The semiconductor device of claim 11, wherein the peripheral circuit structure further includes a vertical conductive pattern penetrating the substrate and the lower insulating layer in a vertical direction perpendicular to the first surface and the second surface of the substrate and electrically connected to the cell array structure.

13. The semiconductor device of claim 12,
wherein the peripheral circuit structure further includes:
a first upper insulating layer disposed on the first surface of the substrate and covering the peripheral transistors; and
peripheral wiring patterns disposed on the first upper insulating layer, and
the vertical conductive pattern penetrating the first upper insulating layer in the vertical direction and is connected to a corresponding peripheral wiring pattern among the peripheral wiring patterns.

14. The semiconductor device of claim 11,
wherein the substrate further includes an upper doping region provided in the substrate between the first well region and the second well region and adjacent to the first surface of the substrate,
wherein the upper doping region includes the first dopant having the first conductive type, and
wherein a concentration of the first dopant in the upper doping region is higher than the concentration of the first dopant in the substrate.

15. The semiconductor device of claim 14, wherein the peripheral circuit structure further includes a peripheral conductive contact disposed on the first surface of the substrate and on the upper doping region.

16. The semiconductor device of claim 11,
wherein the cell array structure includes a plurality of memory cells arranged on the lower substrate,
wherein the plurality of memory cells each include:
a selection element; and
a data storage element connected to one end of the selection element.

17. A semiconductor device comprising:
a substrate having a first surface and a second surface opposite to each other; and
peripheral transistors disposed on the first surface of the substrate,
wherein the substrate includes:
a first well region and a second well region provided in the substrate and spaced apart from each other in a horizontal direction parallel to the first surface and the second surface of the substrate; and
an upper doping region and a lower doping region provided in the substrate between the first well region and the second well region and spaced apart from each other in a vertical direction perpendicular to the first surface and the second surface of the substrate,
wherein the substrate, the upper doping region, and the lower doping region include a first dopant having a first conductive type, and
wherein a concentration of the first dopant in the lower doping region and a concentration of the first dopant in the upper doping region are higher than a concentration of the first dopant in the substrate.

18. The semiconductor device of claim 17, wherein the first well region and the second well region include a second dopant having a second conductive type different from the first conductive type.

19. The semiconductor device of claim 17,
wherein the upper doping region is disposed adjacent to the first surface of the substrate,
wherein the lower doping region is disposed adjacent to the second surface of the substrate, and
wherein at least a portion of the lower doping region is interposed between the first well region and the second well region.

20. The semiconductor device of claim 17, further comprising:
a lower insulating layer disposed on the second surface of the substrate; and
a vertical conductive pattern penetrating the substrate and the lower insulating layer in the vertical direction.
